(19) United States
(12) Patent Application Publication
(10) Pub. No.: US 2026/0096239 A1
(43) Pub. Date: Apr. 2, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Shen-Hui HONG, Tainan City (TW); Ming-Tsong WANG, Taipei City (TW); Jen-Cheng LIU, Hsin-Chu City (TW)

(21) Appl. No.: 18/903,220

(22) Filed: Oct. 1, 2024

(51) Int. Cl. H01L 27/146

(52) U.S. Cl. CPC H10F 39/811; H10F 39/026; H10F 39/803

(57) ABSTRACT

A capacitor structure is included in an interconnect layer of a semiconductor die that is bonded to another semiconductor die in a vertical stack in a semiconductor die. To enable the vertical length of the capacitor structure to be increased, the top electrode layer of the capacitor structure is directly connected to a bonding structure of the semiconductor die as opposed to the top electrode layer of the capacitor structure being connected to the bonding structure through one or more intermediate conductive structures in the interconnect layer. This enables the capacitor structure to vertically extend through a greater quantity of layers of the interconnect layer, which increases the length of the top and bottom electrode layers of the capacitor structure, which increases the capacitance of the capacitor structure. The increased capacitance of the capacitor structure may enable increased performance for the semiconductor device to be achieved.

### BACKGROUND

Various semiconductor device packing techniques may be used to incorporate one or more semiconductor dies into a semiconductor package. In some cases, semiconductor dies may be horizontally interconnected through an interposer. Additionally and/or alternatively, semiconductor dies may be arranged vertically in a semiconductor package to achieve a smaller horizontal or lateral footprint of the semiconductor package and/or to increase the density of the semiconductor package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor device described herein.

FIG. 2 is a diagram of another example implementation of a semiconductor device described herein.

FIGS. 3A and 3B are diagrams of example implementations of a capacitor structure described herein.

FIGS. 4A-4P are diagrams of an example implementation of forming a semiconductor device described herein.

FIGS. 5A-5C are diagrams of an example implementation of forming a semiconductor device described herein.

FIGS. 6A and 6B are diagrams of an example implementation of a semiconductor package described herein.

FIGS. 7A and 7B are diagrams of an example implementation of a semiconductor package described herein.

FIGS. 8A and 8B are diagrams of example implementations of a semiconductor device described herein.

FIG. 9 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device may include a plurality of semiconductor dies that are bonded together in a vertical stack. One or more of the semiconductor dies in the vertical stack may include one or more capacitor structures in an interconnect layer (e.g., a backend region or back end of line (BEOL) region) of the semiconductor die(s). A capacitor structure may include a metal-insulator-metal (MIM) stack in which an insulator layer is sandwiched between two electrode layers: a top electrode layer and a bottom electrode layer. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

However, increasing a lateral size of the capacitor structure is in direct contention with semiconductor design principles in the semiconductor industry, in which reducing semiconductor device sizes is pursued in order to achieve reduced power consumption, achieve greater operating performance and efficiencies, and/or enable semiconductor devices to be used in increasingly smaller form factor applications. Thus, the lateral size of a capacitor structure may not be able to be increased in lateral size in that the lateral area in the semiconductor device may be limited. This can limit the capacitance of the capacitor structure, which may limit the benefits to the performance of the semiconductor device provided by the capacitor structure.

In some implementations described herein, a capacitor structure is included in an interconnect layer of a semiconductor die that is bonded to another semiconductor die in a vertical stack in a semiconductor die. To enable the vertical length of the capacitor structure to be increased, the top electrode layer of the capacitor structure is directly connected to a bonding structure (e.g., a bonding pad, a bonding via) of the semiconductor die, as opposed to the top electrode layer of the capacitor structure being connected to the bonding structure through one or more intermediate conductive structures in the interconnect layer. This enables the capacitor structure to vertically extend through a greater quantity of layers of the interconnect layer, which increases the length of the top and bottom electrode layers of the capacitor structure, which increases the capacitance of the capacitor structure. The increased capacitance of the capacitor structure may enable increased performance for the semiconductor device to be achieved.

For example, the semiconductor device may be an image sensor device (e.g., a three-dimensional complementary metal oxide semiconductor image sensor (3D CIS) device) that includes an image sensor die bonded to an application-specific integrated circuit (ASIC) die.

The image sensor die may include a plurality of pixel sensors arranged in a pixel sensor array. A pixel sensor of the pixel sensor array may include a photodiode configured to convert photons of incident light to a photocurrent. The magnitude of the photocurrent is based at least in part on the intensity of the incident light. Accordingly, if the pixel sensors in the pixel sensor array are capable of sensing incident light across a broad range of intensity, a high range of brightness and contrast may be achieved in images and/or video generated by the semiconductor device.

The pixel sensor may be limited in the number of photons of incident light that can be absorbed before reaching saturation of the pixel sensor. “Saturation” refers to a level of photon absorption past which additional photons of light cannot be absorbed by the pixel sensor. Saturation of the pixel sensor results in limited dynamic range for the pixel sensor because additional brightness and color information cannot be obtained from further absorption of photons. The amount of photocurrent charge that can be stored in a pixel sensor before reaching saturation may be referred to as the full well capacity (FWC) of the pixel sensor. The full well capacity of the pixel sensor may be based at least in part on the size (e.g., the depth, the width, the volume) of the photodiode of the pixel sensor and/or the shape of the photodiode, among other examples. However, while increasing the size of the photodiode may increase the full well capacity of the pixel sensor, doing so may come at the expense of decreasing the density of pixel sensors in the pixel sensor array, which may reduce the resolution of the pixel sensor array.

The capacitor structure may be configured to store charge associated with the photocurrent that is generated by the pixel sensor to increase the FWC of the pixel sensor. The photocurrent may be transferred from the pixel sensor to the capacitor structure, which enables the pixel sensor to generate more charge for the photocurrent than if the photocurrent were wholly stored in the photodiode and/or floating diffusion node of the pixel sensor. Thus, the capacitor structure may increase the FWC of the pixel sensor, which may enable a higher range of brightness and/or contrast to be achieved in images and/or video generated by the pixel sensor array. Moreover, the increased capacitance of the capacitor structure, achieved through connecting the top electrode layer directly to the bonding structure, may further increase the FWC of the pixel sensor by enabling a greater amount of charge to be stored in the capacitor structure, thereby further increasing the performance of the semiconductor device.

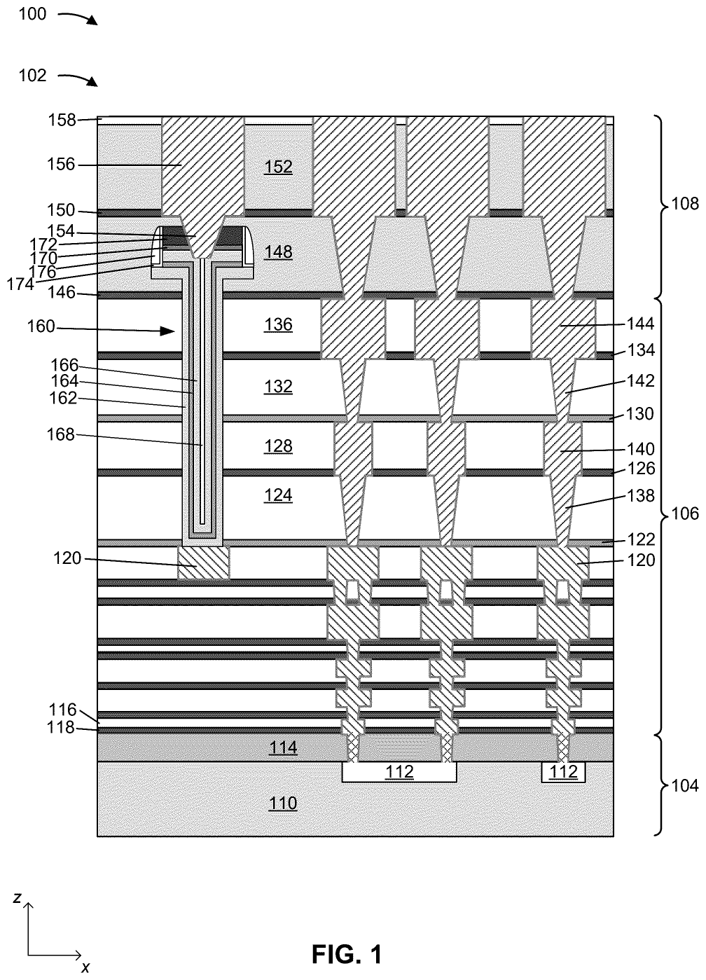

FIG. 1 is a diagram of an example implementation 100 of a semiconductor device 102 described herein. The semiconductor device 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor device 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. In general, the semiconductor device 102 is a semiconductor device that includes one or more capacitor structures in an interconnect layer of the semiconductor device 102.

As shown in FIG. 1, the semiconductor device 102 includes a device layer 104, an interconnect layer 106 vertically arranged (e.g., in a z-direction) in the semiconductor device 102 with the device layer 104, and a bonding layer 108 vertically arranged (e.g., in a z-direction) in the semiconductor device 102 with the interconnect layer 106.

The device layer 104 may also be referred to as a frontend region or a front end of line (FEOL) region of the semiconductor device 102. The device layer 104 includes a substrate layer 110. The substrate layer 110 may correspond to a portion of a semiconductor wafer on which the semiconductor device 102 is formed. The substrate layer 110 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 110 may extend in an x-direction and/or in a y-direction in the semiconductor device 102.

Integrated circuit devices 112 may be included in and/or on the substrate layer 110 in the device layer 104 of the semiconductor device 102. The integrated circuit devices 112 may include frontend transistor structures (e.g., frontend planar transistor structures, frontend fin field effect transistor (finFET) structures, frontend gate all around (GAA) transistor structures), pixel sensors, frontend capacitors, frontend resistors, frontend inductors, photodetectors, transceivers, transmitters, receives, optical circuits, and/or other types of frontend semiconductor devices.

Frontend semiconductor devices refer to the semiconductor devices that are formed in the device layer 104 (e.g., in and/or on the substrate layer 110) of the semiconductor device 102 as opposed to in the interconnect layer 106 of the semiconductor device 102.

A dielectric layer 114 is included over the substrate layer 110. The dielectric layer 114 includes an interlayer dielectric (ILD) layer, an etch stop layer (ESL), and/or another type of dielectric layer. The dielectric layer 114 includes dielectric material(s) that enable various portions of the substrate layer 110 and/or the integrated circuit devices 112 to be selectively etched or protected from etching, and/or to electrically isolate the integrated circuit devices 112 in the device layer 104. The dielectric layer 114 includes a silicon nitride (SiₓN_{y}), an oxide (e.g., a silicon oxide (SiOₓ) and/or another oxide material), and/or another type of dielectric material. The dielectric layer 114 may extend in the x-direction and/or in a y-direction in the semiconductor device 102.

The interconnect layer 106 of the semiconductor device 102 is included above the substrate layer 110 and above the integrated circuit devices 112 in the z-direction in the semiconductor device 102. The integrated circuit devices 112 may be electrically coupled to the interconnect layer 106. The interconnect layer 106 includes a plurality of dielectric layers (e.g., backend dielectric layers) that are arranged in a direction (e.g., the z-direction) that is approximately perpendicular to the substrate layer 110. The dielectric layers may include ILD layers 116 and ESLs 118 that are arranged in an alternating manner in the z-direction. The ILD layers 116 and the ESLs 118 may extend in the x-direction and/or in the y-direction in the semiconductor device 102.

The ILD layers 116 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 116 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 118 may each include a silicon nitride (SiₓN_{y}), silicon carbide (SiC), silicon oxynitride (SiON), and/or another suitable dielectric material. In some implementations, an ILD layer 116 and an ESL 118 include different dielectric materials to provide etch selectivity to enable various structures to be formed in the interconnect layer 106.

The interconnect layer 106 includes a plurality of conductive structures. One or more of the conductive structures 120 are electrically coupled and/or physically coupled with one or more of the integrated circuit devices 112 in the device layer 104. The conductive structures 120 provide electrical routing that enables signals and/or power to be provided to and/or from the integrated circuit devices 112. The conductive structures 120 may include a combination of metallization structures and interconnect structures. The metallization structures may include trenches, metallization layers, conductive traces, and/or other types of metallization structures. The interconnect structures may include vias, plugs, interconnects, and/or another type interconnect structures. The conductive structures 120 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the conductive structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 120 may be arranged in a plurality of layers that are arranged in a vertical manner (e.g., in the z-direction) in the interconnect layer 106. In other words, a plurality of layers of conductive structures 120 extend above the device layer 104 in the interconnect layer 106 to facilitate electrical signals and/or power to be routed between the device layer 104 and the interconnect layer 106. The metallization structures may be arranged in metallization layers referred to as M-layers. For example, a metal-0 (M0) layer that includes a plurality of conductive structures 120 (e.g., metallization structures) may located at the bottom of the interconnect layer 106 and may be directly coupled with the device layer 104 (e.g., with the integrated circuit devices 112 in the device layer 104). A via-1 (V1) layer that includes a plurality of conductive structures (e.g., interconnect structures) may be included above the M0 layer. A metal-1 layer (M1) layer that includes a plurality of conductive structures 120 (e.g., metallization structures) may be located above the V1 layer in the interconnect layer 106, a via-2 (V2) layer that includes a plurality of conductive structures (e.g., interconnect structures) may be included above the M1 layer, a metal-2 layer (M2) layer that includes a plurality of conductive structures 120 (e.g., metallization structures) may be located above the V2 layer, and so on.

One or more top metal layers may be included above the conductive structures 120 (e.g., the M-layers and the V-layers) in the interconnect layer 106. For example, the interconnect layer 106 may include an ESL 122, an ILD layer 124, an ESL 126, an ILD layer 128, an ESL 130, an ILD layer 132, an ESL 134, and an ILD layer 136, and may include a top via 138 (e.g., extending through the ESL 122 and the ILD layer 124), a top metal layer 140 (e.g., extending through the ESL 126 and the ILD layer 128), a top via 142 (e.g., extending through the ESL 130 and the ILD layer 132), and/or a top metal layer 144 (e.g., extending through the ESL 134 and/or the ILD layer 136), among other examples.

The top vias 138 and 142 may be physically larger (e.g., may be taller in the z-direction) than the interconnect structures of the conductive structures 120. Similarly, the top metal layers 140 and 144 may be physically larger (e.g., may be taller in the z-direction) than the metallization structures of the conductive structures 120. For example, the metallization structures of the conductive structures 120 may have sub-micron z-direction heights, whereas the top metal layers 140 and 144 may have z-direction heights of approximately 1 micron or greater. However, other z-direction heights for the metallization structures of the conductive structures 120 and for the top metal layers 140 and 144 are within the scope of the present disclosure.

The physically larger sizes of the top vias 138 and 142 and of the top metal layers 140 and 144 provide for lower sheet resistance and enable higher current signals to be handled at the top of the interconnect layer 106. The physically smaller sizes of the conductive structures 120 enable a higher density of conductive structures 120 to be included closer to the integrated circuit devices 112 in the device layer 104, which enables the integrated circuit devices 112 to be positioned closer together for higher integrated circuit device density in the device layer 104.

In some implementations, the ESLs 122, 126, 130, and 134 may include an alternating arrangement of materials. For example, the ESLs 122 and 130 may include silicon carbide (SiC), and the ESLs 126 and 134 may include a silicon nitride (SiₓN_{y} such as Si₃N₄). However, other combinations of materials for the ESLs 122, 126, 130, and 134 are within the scope of the present disclosure.

In some implementations, the ESL 122 may have a z-direction thickness that is included in a range of approximately 300 angstroms to approximately 800 angstroms. However, other values for the range are within the scope of the present disclosure. In some implementations, the ILD layer 124 may have a z-direction thickness that is included in a range of approximately 4000 angstroms to approximately 8000 angstroms. However, other values for the range are within the scope of the present disclosure. In some implementations, the ESL 126 may have a z-direction thickness that is included in a range of approximately 300 angstroms to approximately 700 angstroms. However, other values for the range are within the scope of the present disclosure. In some implementations, the ILD layer 128 may have a z-direction thickness that is included in a range of approximately 6000 angstroms to approximately 12000 angstroms. However, other values for the range are within the scope of the present disclosure. In some implementations, the ESL 130 may have a z-direction thickness that is included in a range of approximately 300 angstroms to approximately 800 angstroms. However, other values for the range are within the scope of the present disclosure. In some implementations, the ILD layer 132 may have a z-direction thickness that is included in a range of approximately 4000 angstroms to approximately 8000 angstroms. However, other values for the range are within the scope of the present disclosure. In some implementations, the ESL 134 may have a z-direction thickness that is included in a range of approximately 300 angstroms to approximately 700 angstroms. However, other values for the range are within the scope of the present disclosure. In some implementations, the ILD layer 136 may have a z-direction thickness that is included in a range of approximately 7000 angstroms to approximately 10000 angstroms. However, other values for the range are within the scope of the present disclosure.

The bonding layer 108 may be connected to the top metal layer 144 of the interconnect layer 106. The bonding layer 108 may include additional ESLs and dielectric layers, such as an ESL 146, a dielectric layer 148, an ESL 150, and/or a dielectric layer 152, among other examples. Moreover, the bonding layer 108 may include bonding vias 154 (e.g., that extend through the ESL 146 and/or the dielectric layer 148) and bonding pads 156 (e.g., that extend through the ESL 150 and/or the dielectric layer 152). The bonding vias 154 may be electrically connected and/or physically connected to the top metal layer 144, and the bonding pads 156 may be electrically connected and/or physically connected to the bonding vias 154.

The ESLs 146 and 150 may each include a silicon nitride (SiₓN_{y}), silicon carbide (SiC), silicon oxynitride (SiON), and/or another suitable dielectric material. The dielectric layers 148 and 152 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

In some implementations, the ESL 146 may have a z-direction thickness that is included in a range of approximately 500 angstroms to approximately 1000 angstroms. However, other values for the range are within the scope of the present disclosure. In some implementations, the dielectric layer 148 may have a z-direction thickness that is included in a range of approximately 4000 angstroms to approximately 9000 angstroms. However, other values for the range are within the scope of the present disclosure. In some implementations, the ESL 150 may have a z-direction thickness that is included in a range of approximately 800 angstroms to approximately 1600 angstroms. However, other values for the range are within the scope of the present disclosure. In some implementations, the dielectric layer 152 may have a z-direction thickness that is included in a range of approximately 6000 angstroms to approximately 12000 angstroms. However, other values for the range are within the scope of the present disclosure.

The bonding vias 154 include conductive structures that are elongated primarily in the z-direction. The bonding vias 154 may electrically couple the top metal layer 144 to the bonding pads 156. The bonding pads 156 include electrically conductive pads that are used for bonding the semiconductor device 102 to another semiconductor device to form a vertically stacked semiconductor package. The bonding vias 154 and bonding pads 156 include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The bonding layer 108 further includes a bonding dielectric layer 158 around the bonding pads 156. The bonding dielectric layer 158 may also be used to bond the semiconductor device 102 to another semiconductor device to form a vertically stacked semiconductor package. Thus, the combination of the bonding pads 156 and the bonding dielectric layer 158 enables the semiconductor device 102 to be bonded to another semiconductor device in a metal-to-metal bond and in a dielectric-to-dielectric bond. The bonding dielectric layer 158 may include one or more dielectric materials such as a silicon nitride (SiₓN_{y}), silicon carbide (SiC), silicon oxynitride (SiON), and/or another suitable dielectric material. In some implementations, a z-direction thickness of the bonding dielectric layer 158 may be included in a range of approximately 500 angstroms to approximately 1000 angstroms. However, other values for the range are within the scope of the present disclosure.

As further shown in FIG. 1, the semiconductor device 102 may include one or more capacitor structures 160. A capacitor structure 160 may include a trench capacitor structure that is included in and extends through a portion of the bonding layer 108, and is included in and extends through a portion of the interconnect layer 106. The capacitor structure 160 may include a deep trench capacitor (DTC) structure in that the capacitor structure 160 has a high aspect ratio between a vertical (z-direction) height of the capacitor structure 160 and a lateral (x-direction) width of the capacitor structure 160. For example, the aspect ratio of the capacitor structure 160 may be greater than approximately 10:1, and in some implementations is included in a range of approximately 18:1 to approximately 55:1. However, other values and ranges for the aspect ratio for the capacitor structure 160 are within the scope of the present disclosure.

The high aspect ratio of the capacitor structure 160 is achieved at least in part by directly connecting the top of the capacitor structure 160 to a bonding via 154 in the bonding layer 108, as opposed to connecting the top of the capacitor structure 160 to a conductive structure 120 or a top metallization layer in the interconnect layer 106. The direct connection of the top of the capacitor structure 160 to the bonding via 154 enables the capacitor structure 160 to be included in and extend through a portion of the bonding layer 108, as well as in and through a portion of the interconnect layer 106. This may enable the capacitance of the capacitor structure 160 to be increased up to 5 times the capacitance or greater than if the capacitor structure 160 only extended through the interconnect layer 106.

As shown in FIG. 1, the capacitor structure 160 includes a plurality of conformal layers that conform to the profile of a trench that extends through a plurality of dielectric layers of the interconnect layer 106 and the bonding layer 108. The trench may extend through, for example, the ESLs 122, 126, 130, and 134 of the interconnect layer 106, the ILD layers 124, 128, 132, and 136 of the interconnect layer, the ESL 146 of the bonding layer 108, and/or the dielectric layer 148 of the bonding layer 108. The trench may extend to a conductive structure 120 in the interconnect layer 106 such that a bottom of the capacitor structure 160 is electrically connected to the conductive structure 120.

The conformal layers may include a bottom electrode layer 162, an insulator layer 164 on the bottom electrode layer 162, and a top electrode layer 166 on the insulator layer 164.

Thus, the insulator layer 164 is located between the bottom electrode layer 162 and the top electrode layer 166, which enables the capacitor structure 160 to store an electrical charge based on the capacitance between the bottom electrode layer 162 and the top electrode layer 166. The bottom electrode layer 162, the insulator layer 164, and the top electrode layer 166 may be conformal layers that extend along the sidewalls and the bottom surface of the trench in which the capacitor structure 160 is formed. A dielectric filler 168 may be included in the trench to electrically isolate segments of the top electrode layer 166 on opposing sidewalls of the trench. However, in other implementations, the dielectric filler 168 is omitted, and the top electrode layer 166 fills in the remaining area of the trench.

As shown in FIG. 1, the portion of the bottom electrode layer 162 at the bottom of the capacitor structure 160 may be on, and in physical contact with, the conductive structure 120 at the bottom of the capacitor structure 160. Thus, the bottom electrode layer 162 may be electrically connected to the conductive structure 120 in the interconnect layer 106. The portion of the top electrode layer 166 at the top of the capacitor structure 160 may be in physical contact with (e.g., direct physical contact with) the bonding via 154 at the top of the capacitor structure 160. Thus, the top electrode layer 166 may be directly electrically connected to the bonding via 154 in the bonding layer 108.

The bottom electrode layer 162, the insulator layer 164, and the top electrode layer 166 correspond to an MIM stack of the capacitor structure 160. Thus, the capacitor structure 160 may also be referred to as an MIM capacitor structure. The bottom electrode layer 162 (also referred to as a capacitor bottom metal (CBM)) and the top electrode layer 166 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), tantalum (Ta), aluminum (Al), copper (Cu), gold (Au), titanium nitride (TiN), and/or tantalum nitride (TaN), among other examples. In some implementations, the bottom electrode layer 162 and the top electrode layer 166 include the same material or the same material composition. In some implementations, the bottom electrode layer 162 and the top electrode layer 166 include different materials or different material compositions.

The insulator layer 164 may include one or more electrically insulating materials. In some implementations, the insulator layer 164 includes one or more low-k dielectric materials such as silicon oxide (SiOₓ such as SiO₂). Additionally and/or alternatively, the insulator layer 164 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 164 is a multiple-layer stack that includes a plurality of dielectric layers. For example, the insulator layer 164 may include a ZrO₂/Al₂O₃/ZrO₂ (ZAZ) layer stack.

As further shown in FIG. 1, the capacitor structure 160 may include one or more capping layers above the top electrode layer 166. The one or more capping layers may include a capping layer 170, a capping layer 172, and/or another capping layer. The capping layers may provide electrical isolation for the MIM stack of the capacitor structure 160, and/or may also function as a hard mask layer stack for forming a recess for the bonding via 154. The capping layers 170 and 172 may include an oxide-containing dielectric material such as silicon oxide (SiOₓ such as SiO₂), an oxynitride-containing dielectric material such as silicon oxynitride (SiON), a nitride-containing dielectric material such as silicon nitride (SiₓN_{y} such as Si₃N₄), and/or another suitable dielectric material. In some implementations, the capping layers 170 and 172 include the same material and/or the same material composition. In some implementations, the capping layers 170 and 172 include different materials and/or different material compositions.

The bonding via 154 connected to the top electrode layer 166 of the capacitor structure 160 may extend through the capping layers 170 and 172. In some implementations, the bonding via 154 connected to the top electrode layer 166 of the capacitor structure 160 may extend into the top electrode layer 166 such that the bottom surface of the bonding via 154 is recessed in the top electrode layer 166.

As further shown in FIG. 1, the capacitor structure 160 may include one or more sidewall spacers 174 and/or 146 on the sidewalls of the capping layers 170 and/or 172, and/or on sidewalls of the top electrode layer 166 at the top of the capacitor structure 160. The combination of the capping layers 170, 172 and the sidewall spacers 174, 176 may be used as a self-aligned mask when etching a layer to define the bottom electrode layer 162. The sidewall spacer 174 may include an oxide-containing dielectric material such as silicon oxide (SiOₓ such as SiO₂), among other examples. The sidewall spacer 176 may include a nitride-containing dielectric material such as silicon nitride (SiₓN_{y} such as Si₃N₄), among other examples.

As indicated above, FIG. 1 is provided as an example. Other examples may differ from what is described with regard to FIG. 1.

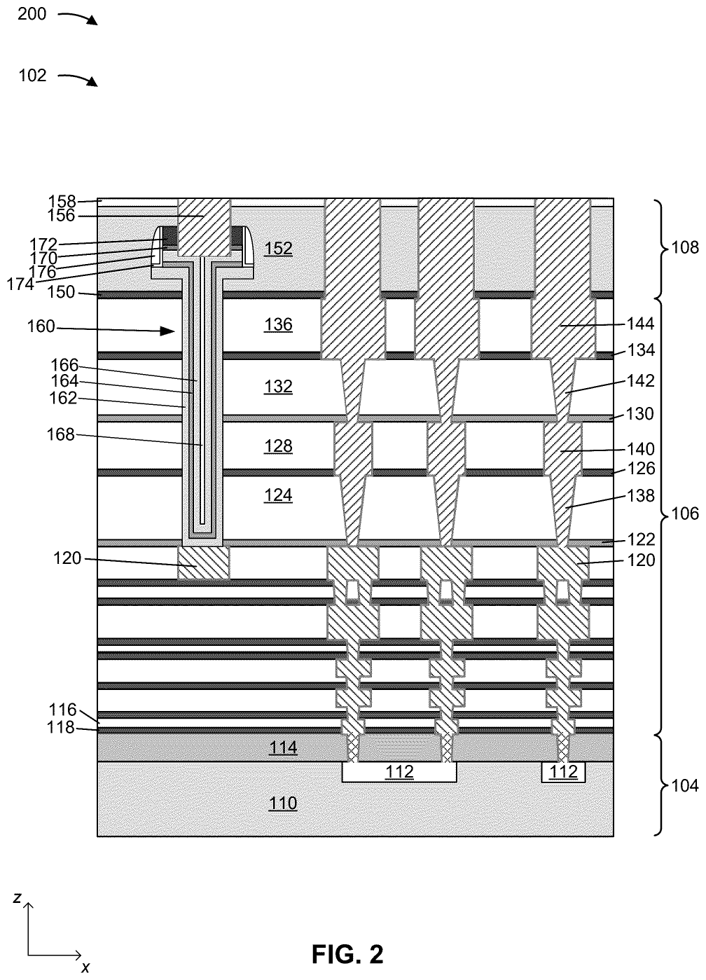

FIG. 2 is a diagram of another example implementation 200 of the semiconductor device 102 described herein. As shown in FIG. 2, the example implementation 200 of the semiconductor device 102 may include a similar combination and arrangement of layers and/or structures as the example implementation 100 of the semiconductor device 102 illustrated in FIG. 1. However, in the example implementation 200 in FIG. 2, the ESL 146, the dielectric layer 148, and the bonding vias 154 are omitted from the semiconductor device 102. Instead, the bonding pads 156 are directly connected (e.g., physically and/or electrically) to the top metal layer 144, as well as directly connected (e.g., physically and/or electrically) to the top electrode layer 166 of the capacitor structure 160.

As shown in FIG. 2, the ESL 150 may be included on the ILD layer 136, the dielectric layer 152 may be included on the ESL 150, and the bonding dielectric layer 158 may be included on the dielectric layer 152. The top of the capacitor structure 160 may be included in the dielectric layer 152. In some implementations, a vertical (z-direction) thickness of the dielectric layer 152 in the example implementation 200 of the semiconductor device 102 may be included in a range of approximately 6800 angstroms to approximately 16600 angstroms. However, other values and ranges are within the scope of the present disclosure.

The bonding pad 156 connected to the top electrode layer 166 of the capacitor structure 160 may extend through the capping layers 170 and 172. In some implementations, the bonding pad 156 connected to the top electrode layer 166 of the capacitor structure 160 may extend into the top electrode layer 166 such that the bottom surface of the bonding pad 156 is recessed in the top electrode layer 166.

As indicated above, FIG. 2 is provided as an example. Other examples may differ from what is described with regard to FIG. 2.

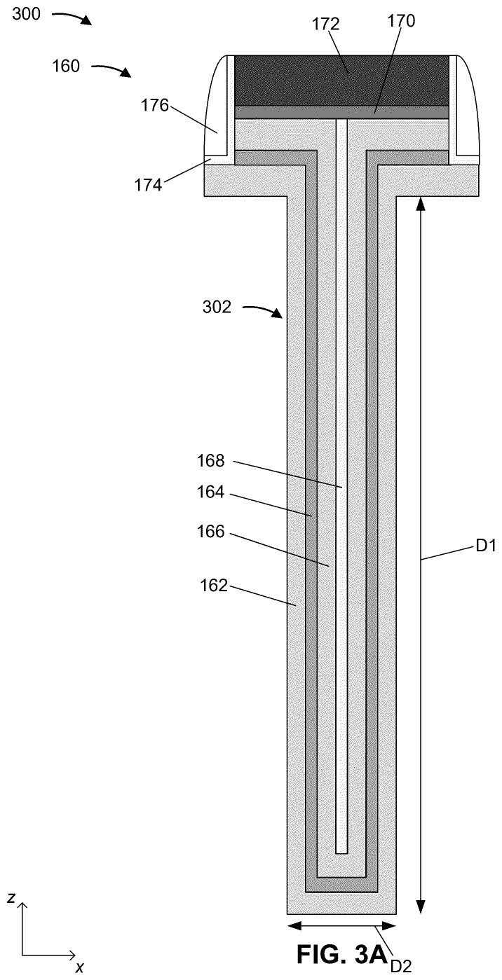

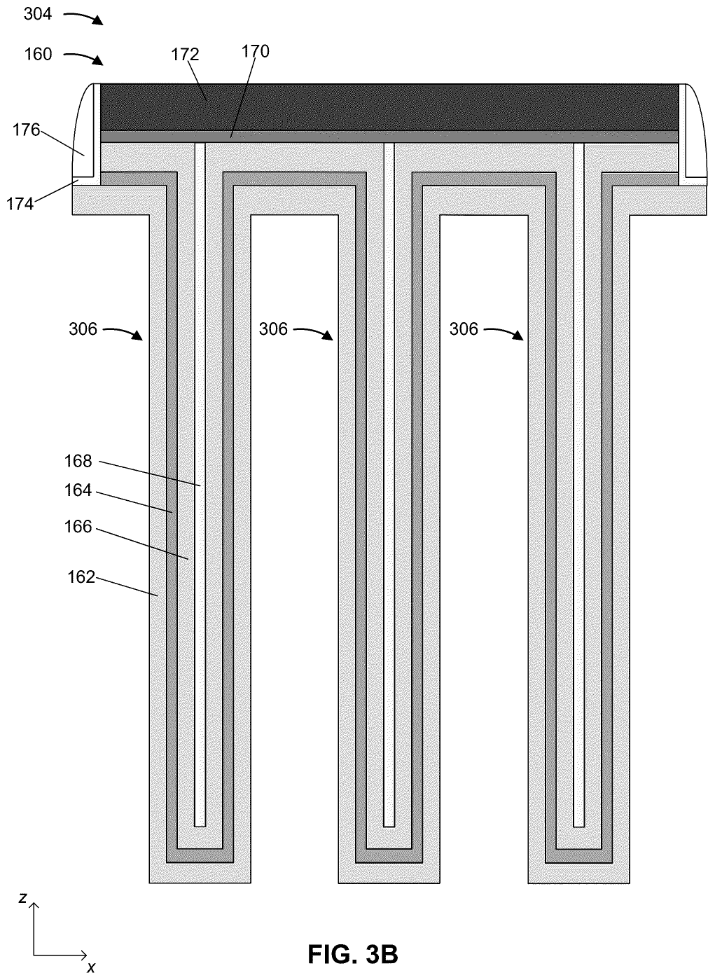

FIGS. 3A and 3B are diagrams of example implementations of a capacitor structure 160 described herein. As shown in an example implementation 300 in FIG. 3A, a capacitor structure 160 may have an elongated body (or finger) 302 that extends in the z-direction. The elongated body 302 may extend into a trench formed in a plurality of dielectric layers in an interconnect layer 106 and in a bonding layer 108 of a semiconductor device 102 described herein. In some implementations, a vertical (z-direction) height (or depth) of the elongated body 302 (indicated in FIG. 3A as a dimension D1) may be included in a range of approximately 3 microns to approximately 6 microns. In some implementations, a lateral (x-direction) width of the elongated body 302 (indicated in FIG. 3A as a dimension D2) may be included in a range of approximately 500 angstroms to approximately 3300 angstroms. However, other values and ranges for these dimensions are within the scope of the present disclosure.

As shown in an example implementation 304 in FIG. 3B, a capacitor structure 160 may include a plurality of fingers 306 that each extend in the z-direction. The bottom electrode layer 162, the insulator layer 164, and/or the top electrode layer 166 may continuously extend through and between each of the fingers 306, and may conform to the cross-sectional profile of each of the fingers 306. In some implementations, a capacitor structure 160 may include 1 to 10 fingers 306. However, other quantities of fingers 306 for a capacitor structure 160 are within the scope of the present disclosure.

As indicated above, FIGS. 3A and 3B are provided as examples. Other examples may differ from what is described with regard to FIGS. 3A and 3B.

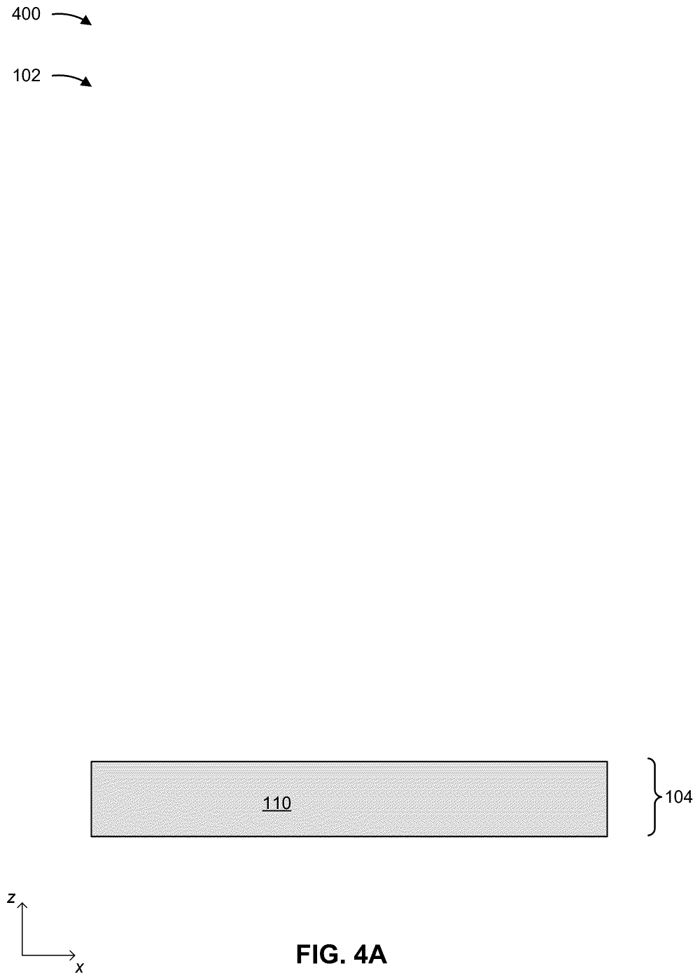

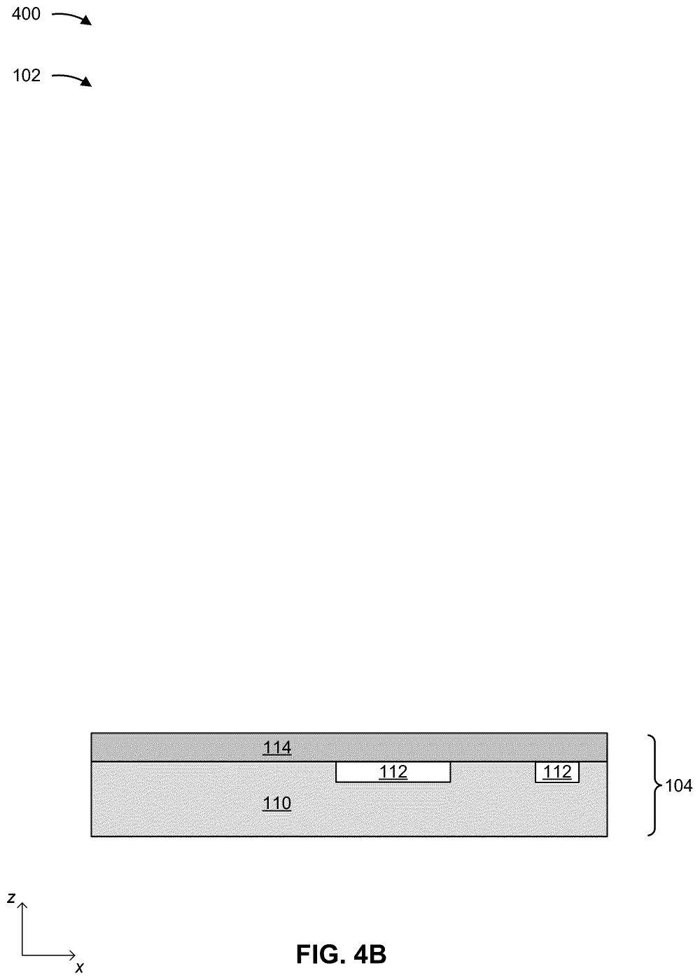

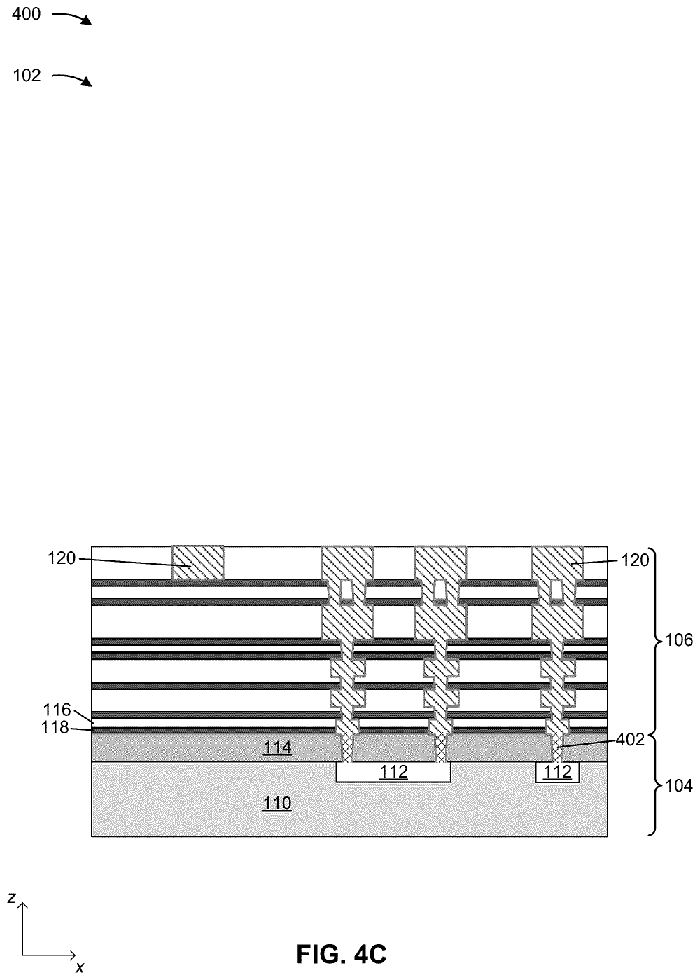

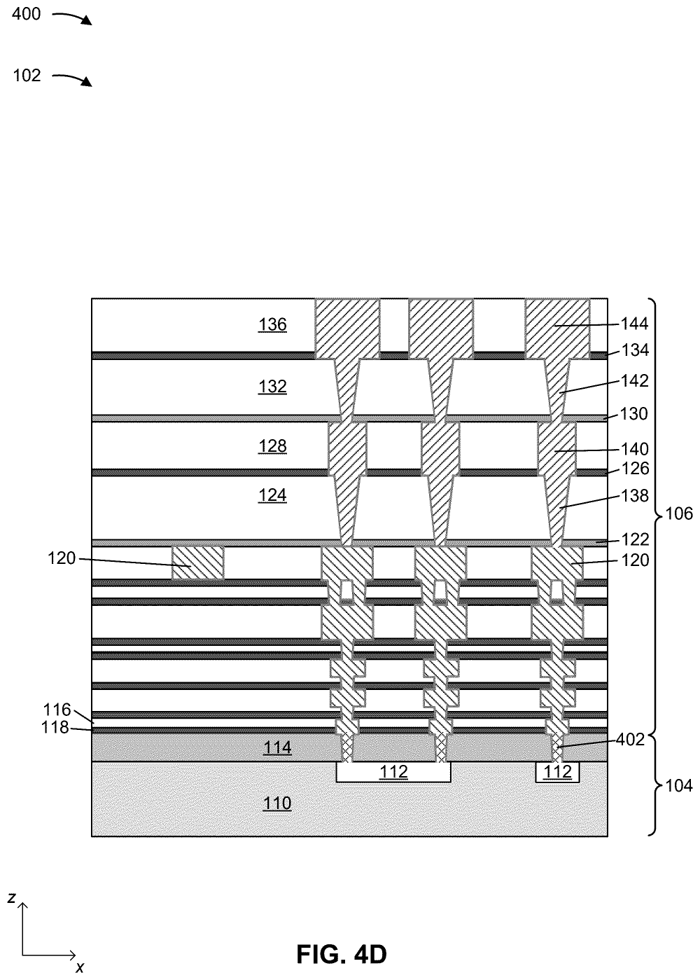

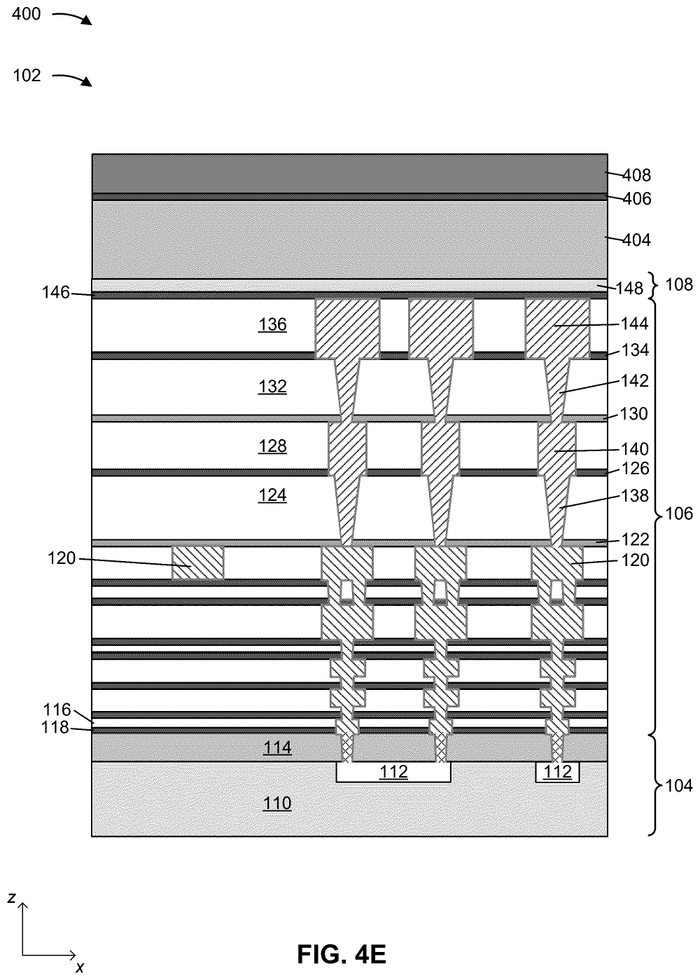

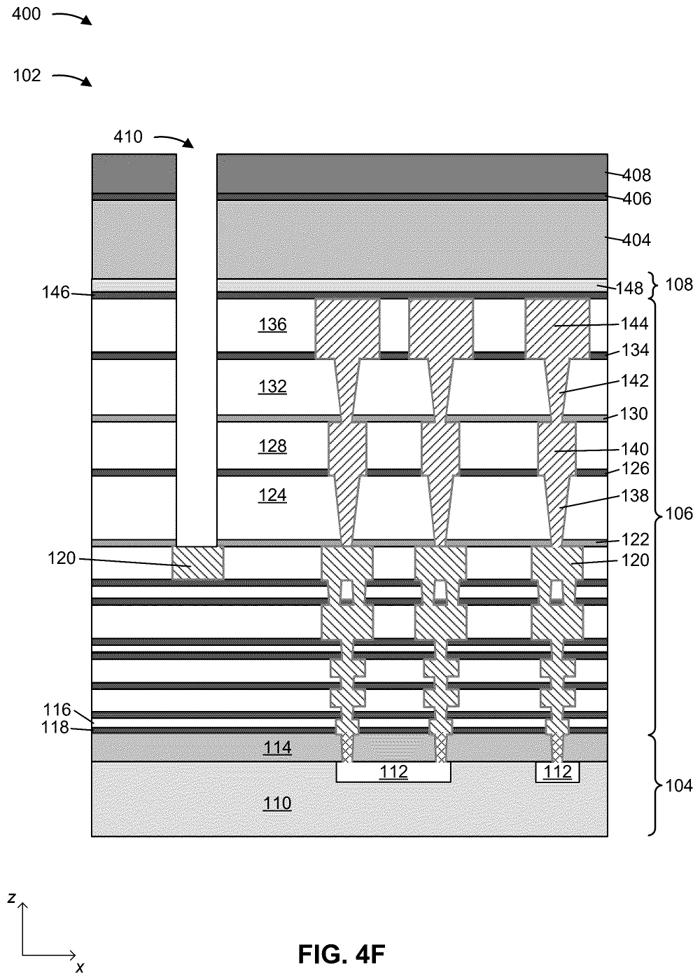

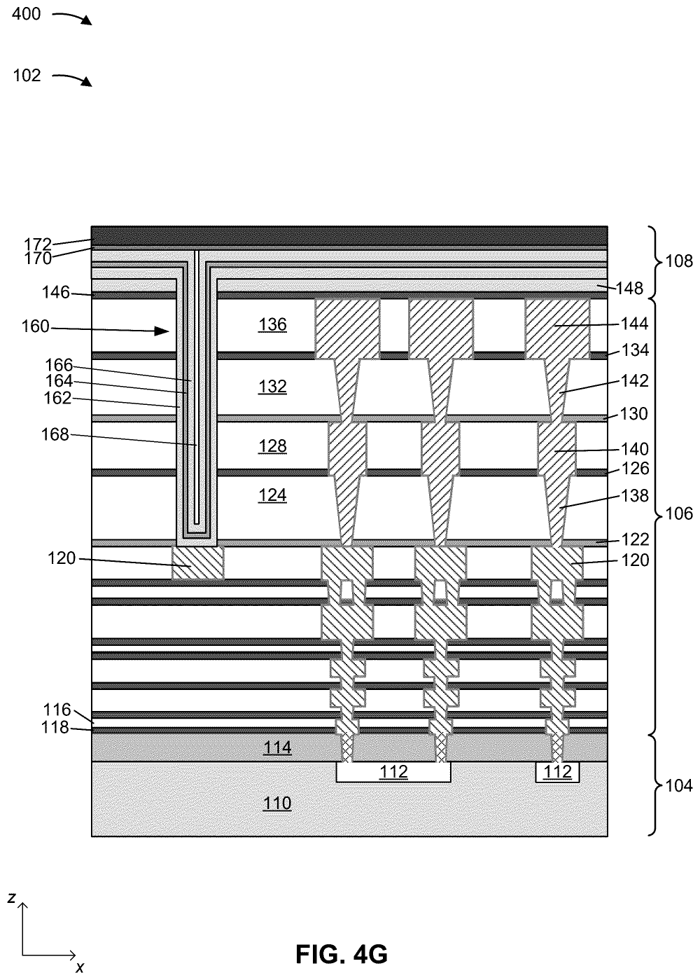

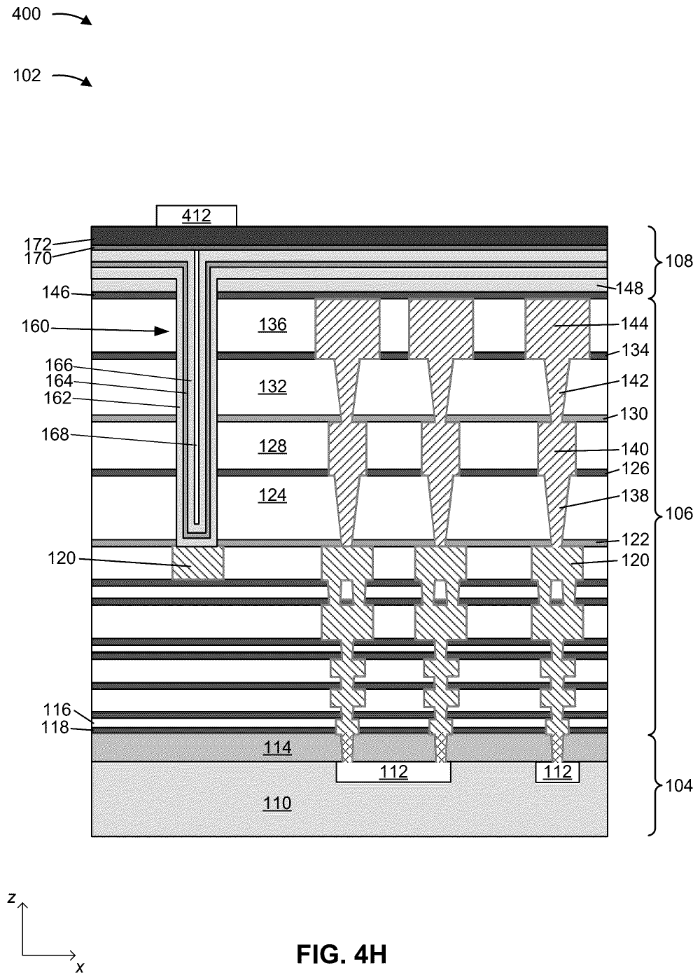

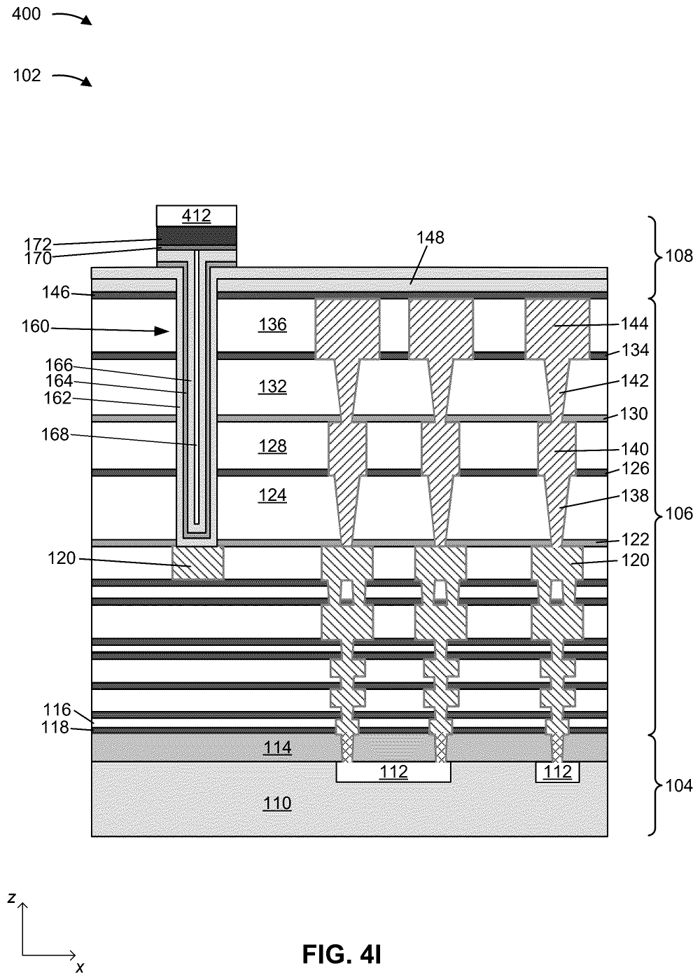

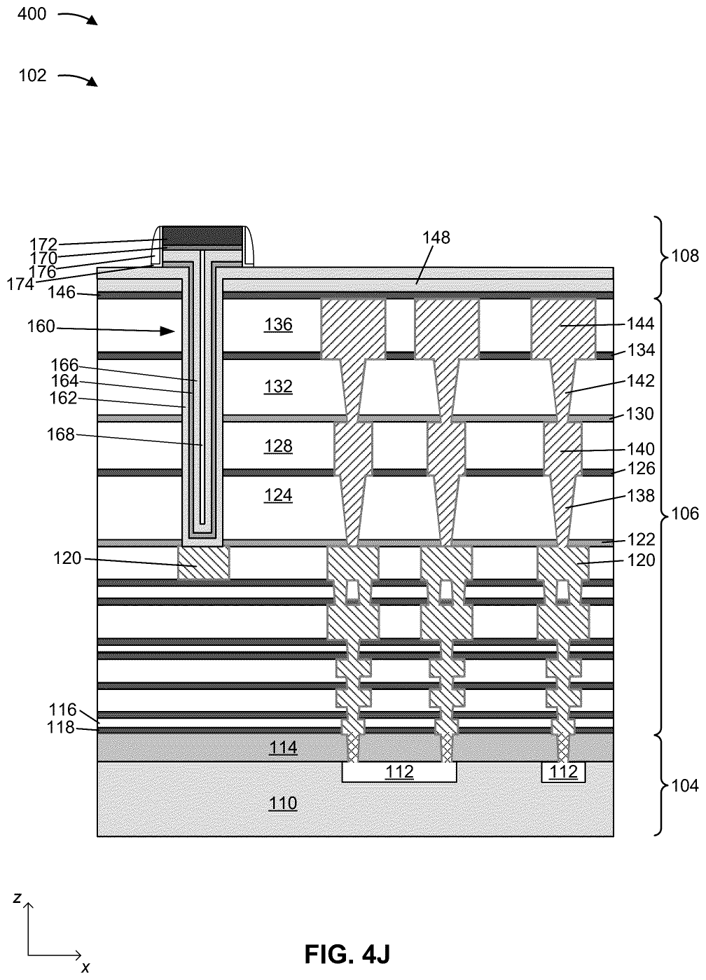

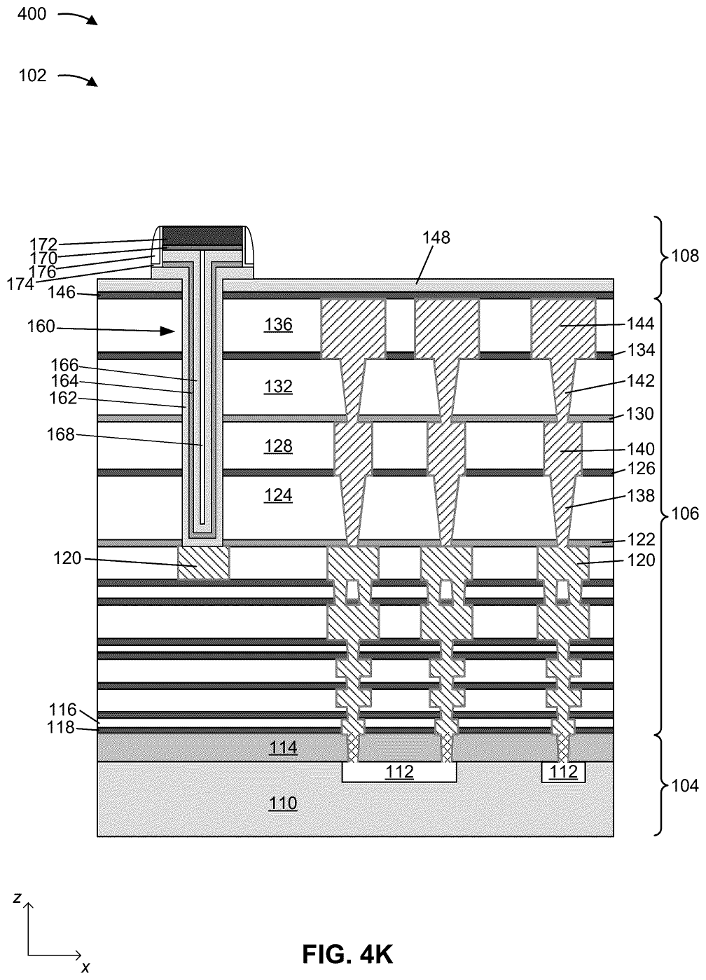

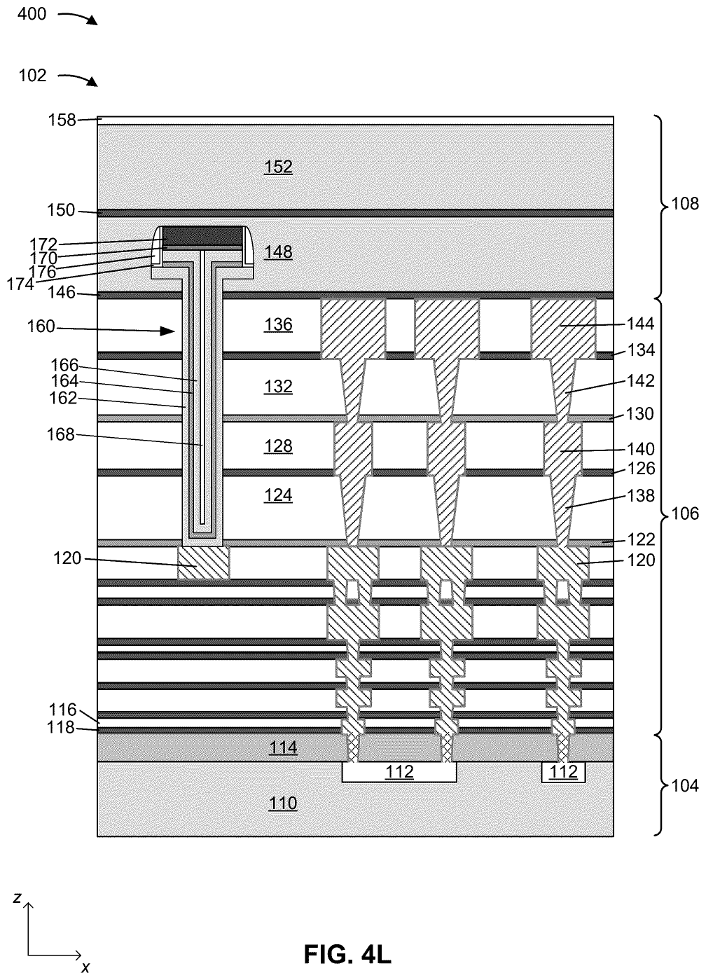

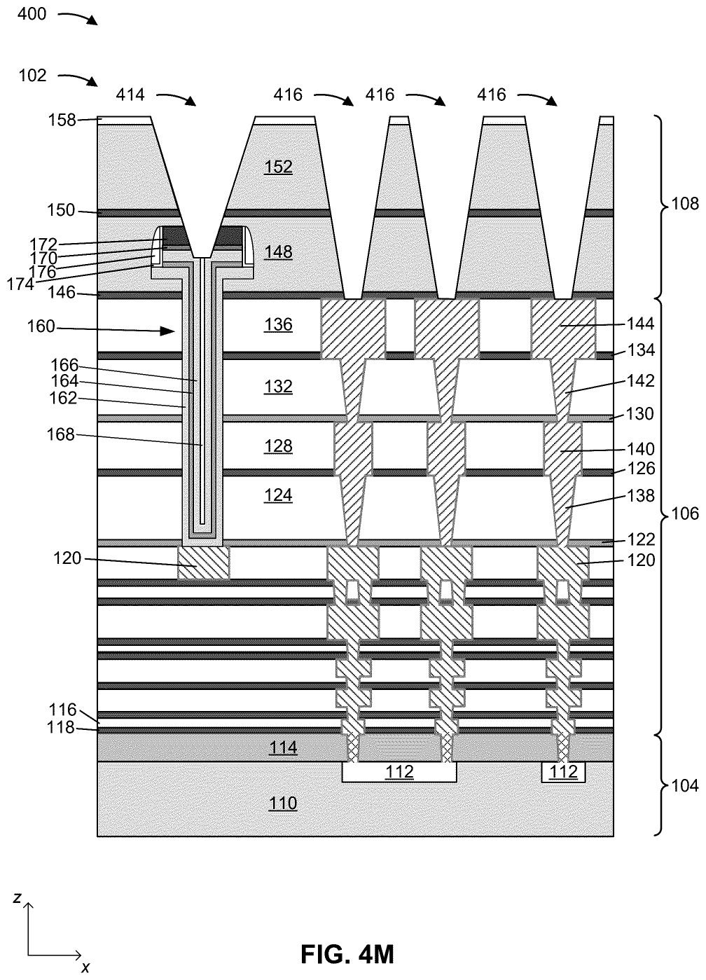

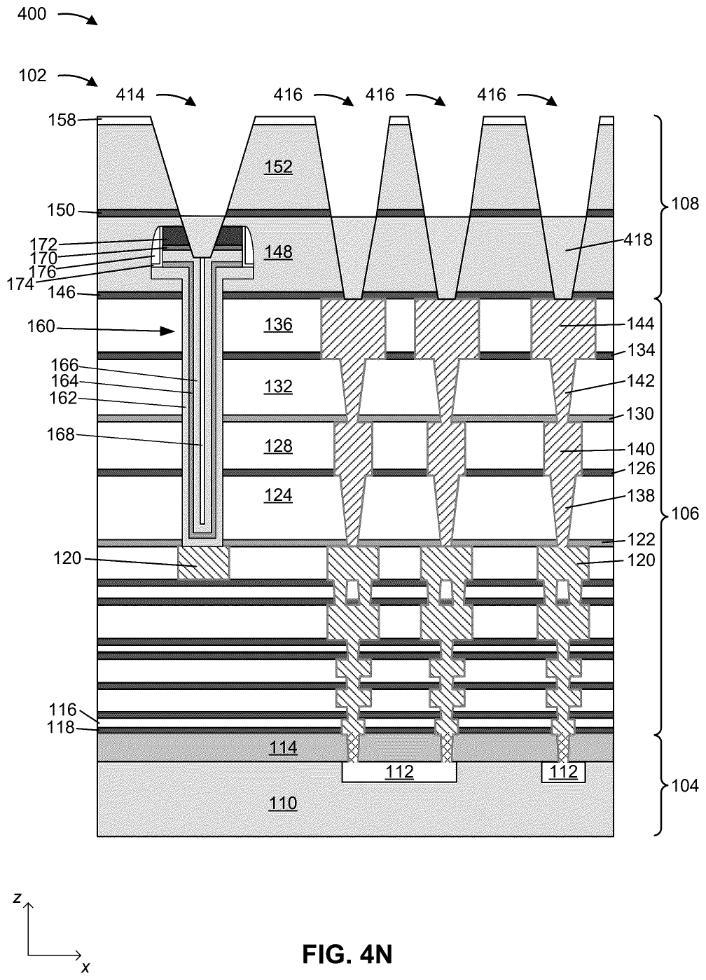

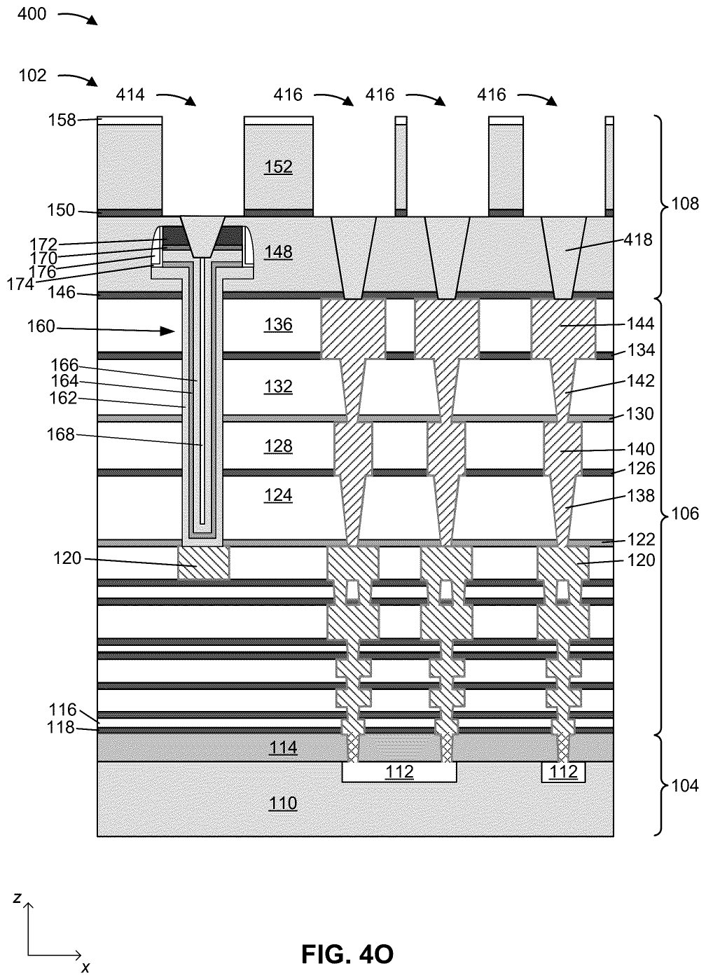

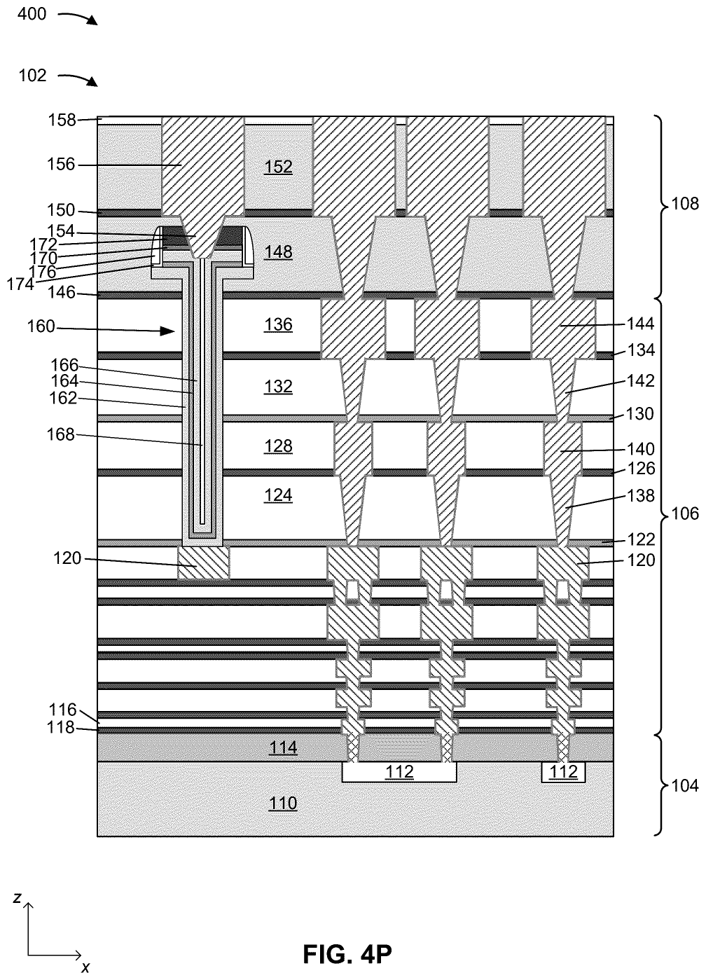

FIGS. 4A-4P are diagrams of an example implementation 400 of forming a semiconductor device 102 described herein. In particular, the example implementation 400 includes an example of forming the example implementation 100 of the semiconductor device 102 illustrated in FIG. 1. However, one or more of the semiconductor processing operations described in connection with FIGS. 4A-4P may be performed to form another example implementation of a semiconductor device 102 described herein. In some implementations, one or more of the semiconductor processing operations described in connection with FIGS. 4A-4P may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 4A, the substrate layer 110 may be provided. The substrate layer 110 may be provided in the form of a semiconductor wafer such as a silicon (Si) wafer, an SOI wafer, and/or another type of semiconductor work piece. The semiconductor device 102 may be formed on the semiconductor wafer with other semiconductor devices.

As shown in FIG. 4B, the integrated circuit devices 112 may be formed in and/or on the substrate layer 110 in the device layer 104 of the semiconductor device 102. One or more semiconductor processing tools may be used to form one or more portions of the integrated circuit devices 112. For example, an ion implantation tool may be used to dope one or more regions in the substrate layer 110 with one or more types of dopants to form well regions, implant regions, and/or other types of doped regions in the substrate layer 110 for the integrated circuit devices 112. As another example, a deposition tool may be used to perform various deposition operations to deposit layers and/or structures of the integrated circuit devices 112, and/or to deposit photoresist layers for etching the substrate layer 110 and/or portions of the deposited layers. As another example, an exposure tool may be used to expose the photoresist layers to form patterns in the photoresist layers. As another example, a developer tool may be used to develop the patterns in the photoresist layers. As another example, an etch tool may be used to etch the substrate layer 110 and/or portions of the deposited layers to form the integrated circuit devices 112. As another example, a planarization tool may be used to planarize portions of the integrated circuit devices 112. As another example, a plating tool may be used to deposit metal structures and/or layers of the integrated circuit devices 112.

As further shown in FIG. 4B, a deposition tool is used to deposit the dielectric layer 114 over and/or on the substrate layer 110 and over and/or on the integrated circuit devices 112. A deposition tool may be used to deposit the dielectric layer 114 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation, such as a chemical mechanical planarization (CMP) operation, to planarize the dielectric layer 114 after the dielectric layer 114 is deposited.

As shown in FIG. 4C, contacts 402 of the integrated circuit devices 112 may be formed through the dielectric layer 114. The contacts 402 may be formed in recesses in the dielectric layer 114. In some implementations, a pattern in a photoresist layer is used to etch the dielectric layer 114 to form the recesses. In these implementations, a deposition tool may be used to form the photoresist layer on the dielectric layer 114. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 114 based on a pattern to form the recesses.

The contacts 402 may be formed in the recesses. In some implementations, a contact 402 (e.g., a gate contact) is formed on a gate structure of an integrated circuit device 112. In some implementations, a contact 402 (e.g., a source/drain contact) is formed on a source/drain region of an integrated circuit device 112. A deposition tool may be used to deposit the material of the contacts 402 in the recesses using a CVD technique, a PVD technique, an ALD technique, an electroplating technique, and/or another suitable deposition technique. The material of the contacts 402 may be deposited in one or more deposition operations. In some implementations, a seed layer is first deposited, and the material of the contacts 402 is deposited on the seed layer. In some implementations, a planarization tool is used to perform a planarization operation (e.g., a CMP operation) to planarize the contacts 402 after the contacts 402 are deposited such that the tops of the contacts 402 are approximately co-planar with the top of the dielectric layer 114.

As shown in FIG. 4C, a first portion of the interconnect layer 106 of the semiconductor device 102 is formed above the dielectric layer 114. One or more deposition tools are used to deposit alternating layers of ILD layers 116 and ESLs 118 in the first portion of the interconnect layer 106 of the semiconductor device 102. In this way, the ILD layers 116 and ESLs 118 may be arranged in the z-direction in the semiconductor device 102. One or more deposition tools may be used to deposit each of the ILD layers 116 and each of the ESLs 118 using a PVD technique, an ALD technique, a CVD technique, an oxidation technique, and/or another suitable deposition technique. In some implementations, a planarization tool may be used to planarize the ILD layers 116 and/or the ESLs 118 after the ILD layers 116 and/or the ESLs 118 are deposited.

As further shown in FIG. 4C, a deposition tool, an exposure tool, a developer tool, an etch tool, a planarization tool, a plating tool, and/or another semiconductor processing tool may be used to perform various operations to form the conductive structures 120 in the first portion of the interconnect layer 106 of the semiconductor device 102. In some implementations, the first portion of the interconnect layer 106 may be formed in a plurality of layers. For example, an ILD layer 116 and an ESL 118 may be formed (e.g., using one or more deposition tools and/or one or more planarization tools), recesses may be formed in and/or through the ILD layer 116 and the ESL 118 (e.g., using an exposure tool, a developer tool, and/or an etch tool), and a first layer (e.g., the M0 layer) of conductive structures 120 (e.g., of metallization structures) may be formed in the ILD layer 116 and the ESL 118 (e.g., using one or more deposition tools and/or one or more planarization tools). Another ILD layer 116 and another ESL 118 may be formed, and a second layer (e.g., the V0 layer) of conductive structures 120 (e.g., of interconnect structures) may be formed in the ILD layer 116 and the ESL 118. Additional layers of conductive structures 120 may be formed in the interconnect layer 106 a similar manner.

One or more deposition tools may be used to deposit the conductive structures 120 using a PVD technique, an ALD technique, a CVD technique, an electroplating technique (e.g., an electro-chemical plating technique), and/or another suitable deposition technique. In some implementations, a planarization tool may be used to planarize the conductive structures 120 after the conductive structures 120 are deposited.

As shown in FIG. 4D, a second portion of the interconnect layer 106 of the semiconductor device 102 is formed above the first portion of the interconnect layer 106. The second portion of the interconnect layer 106 may include the ESLs 122, 126, 130, and 134, the ILD layers 124, 128, 132, and 136, the top vias 138 and 142, and the top metal layers 140 and 144. One or more deposition tools are used to deposit the ESLs 122, 126, 130, 134 and the ILD layers 124, 128, 132, 136 using a PVD technique, an ALD technique, a CVD technique, an oxidation technique, and/or another suitable deposition technique. In some implementations, a planarization tool may be used to planarize the ESLs 122, 126, 130, 134 and the ILD layers 124, 128, 132, 136.

As further shown in FIG. 4D, a deposition tool, an exposure tool, a developer tool, an etch tool, a planarization tool, a plating tool, and/or another semiconductor processing tool may be used to perform various operations to form the top vias 138, 142 and the top metal layers 140, 144 in the second portion of the interconnect layer 106 of the semiconductor device 102. In some implementations, the ESL 122 and the ILD layer 124 may be formed, recesses may be formed in and/or through the ESL 122 and the ILD layer 124 (e.g., using an exposure tool, a developer tool, and/or an etch tool), and the top vias 138 may be formed in the recesses (e.g., using one or more deposition tools and/or one or more planarization tools). In some implementations, the ESL 126 and the ILD layer 128 may be formed, recesses may be formed in and/or through the ESL 126 and the ILD layer 128 (e.g., using an exposure tool, a developer tool, and/or an etch tool), and the top metal layers 140 may be formed in the recesses (e.g., using one or more deposition tools and/or one or more planarization tools). In some implementations, the ESL 130 and the ILD layer 132 may be formed, recesses may be formed in and/or through the ESL 130 and the ILD layer 132 (e.g., using an exposure tool, a developer tool, and/or an etch tool), and the top vias 142 may be formed in the recesses (e.g., using one or more deposition tools and/or one or more planarization tools). In some implementations, the ESL 134 and the ILD layer 136 may be formed, recesses may be formed in and/or through the ESL 134 and the ILD layer 136 (e.g., using an exposure tool, a developer tool, and/or an etch tool), and the top metal layers 144 may be formed in the recesses (e.g., using one or more deposition tools and/or one or more planarization tools).

One or more deposition tools may be used to deposit the top vias 138, 142 and the top metal layers 140, 144 using a PVD technique, an ALD technique, a CVD technique, an electroplating technique (e.g., an electro-chemical plating technique), and/or another suitable deposition technique. In some implementations, a planarization tool may be used to planarize the top vias 138, 142 and the top metal layers 140, 144 after the top vias 138, 142 and the top metal layers 140, 144 are deposited.

As shown in FIG. 4E, the ESL 146 and a portion of the dielectric layer 148 of the bonding layer 108 may be formed above the interconnect layer 106. A deposition tool may be used to deposit the ESL 146 and the portion of the dielectric layer 148 using a PVD technique, an ALD technique, a CVD technique, an oxidation technique, and/or another suitable deposition technique. The ESL 146 and the portion of the dielectric layer 148 may be deposited in one or more deposition operations. In some implementations, a planarization tool may be used to perform a planarization operation (e.g., a CMP operation) to planarize the ESL 146 and the portion of the dielectric layer 148 after the ESL 146 and the portion of the dielectric layer 148 are deposited.

As further shown in FIG. 4E, a patterning stack may be formed above the portion of the dielectric layer 148. The patterning stack may include a plurality of masking layers that are used to form a recess in which a capacitor structure 160 may be formed in the semiconductor device 102. The masking layers may include an advanced patterning film (APF) layer 404, a bottom anti-reflective coating (BARC) 406 on the APF layer 404, and/or a photoresist layer 408 on the BARC 406, among other examples. The masking layers of the patterning stack may be selected to form the recess for the capacitor structure 160 in a highly controlled manner to achieve substantially vertical sidewalls (and thus, a high aspect ratio) for the capacitor structure 160. The APF layer 404 may include an amorphous carbon material and/or another suitable material. The BARC 406 may include silicon oxynitride (SiON), a polymer, and/or another suitable material. A deposition tool may be used to deposit the APF layer 404, the BARC 406, and/or the photoresist layer 408 using a PVD technique, a CVD technique, and ALD technique, a spin-coating technique, and/or another suitable deposition technique.

As shown in FIG. 4F, an etch tool may be used to etch through the portion of the dielectric layer 148, through the ESL 146, through the ILD layer 136, through the ESL 134, through the ILD layer 132, through the ESL 130, through the ILD layer 128, through the ESL 126, through the ILD layer 124, and/or through the ESL 122 to form a recess 410. The recess 410 extends through the bonding layer 108 and into the interconnect layer 106 to an underlying conductive structure 120 in the interconnect layer 106. The recess 410 may include a trench, a hole, a via, and/or another type of recess.

In some implementations, a pattern is formed in the photoresist layer 408, and the pattern is used to form the recess 410. An exposure tool may be used to expose the photoresist layer 408 to a radiation source to pattern the photoresist layer 408. A developer tool may be used to develop and remove portions of the photoresist layer 408 to expose the pattern. An etch tool may be used to etch the BARC 406 and/or the APF layer 404 based on the pattern to transfer the pattern to the BARC 406 and/or to the APF layer 404. An etch tool may be used to etch through the ILD layer 136, through the ESL 134, through the ILD layer 132, through the ESL 130, through the ILD layer 128, through the ESL 126, through the ILD layer 124, and/or through the ESL 122 based on the pattern in the photoresist layer 408, in the BARC 406, and/or in the APF layer 404 to form the recess 410. In some implementations, the etch operation to form the recess 410 includes a dry etch operation (e.g., a plasma-based etch operation, a gas-based etch operation), a wet chemical etch operation, and/or another type of etch operation.

In some implementations, a deep reactive ion etch technique (sometimes referred to as a “BOSCH” etch technique) may be used to achieve the high aspect ratio for the recess 410. A deep reactive ion etch technique is a cyclic etch technique in which a plurality of deposition and etch cycles are performed using protective liners to minimize lateral etching. For example, a deep reactive ion etch cycle may include etching the recess 410 to a first depth, forming a protective liner on the sidewalls and bottom surface of the recess 410, etching the protective liner to remove the protective liner from the bottom surface of the recess 410, and etching the bottom of the recess 410 to increase the depth of the recess 410 to a second depth while the protective liner protects the sidewalls of the recess 410 from lateral etching. Additional cycles may be performed to achieve a particular depth for the recesses 410.

As shown in FIG. 4G, a photoresist removal tool may be used to remove the remaining portions of the photoresist layer 408 (e.g., using a chemical stripper, plasma ashing, and/or another technique). Moreover, an etch tool and/or a planarization tool may be used to remove the remaining portions of the BARC 406 and/or the remaining portions of the APF layer 404.

As further shown in FIG. 4G, the bottom electrode layer 162, the insulator layer 164, the top electrode layer 166, and the dielectric filler 168 may be formed in the recess 410. The bottom electrode layer 162 may be conformally deposited on the sidewalls and on the bottom surface (which corresponds to the top surface of the conductive structure 120 exposed through the recess 410) of the recess 410. The bottom electrode layer 162 may also be deposited on the top surface of the portion of the dielectric layer 148. In some implementations, a conformal CVD technique and/or an ALD technique is used to deposit the bottom electrode layer 162.

The insulator layer 164 may be deposited on the bottom electrode layer 162. Thus, the insulator layer 164 is deposited on the sidewalls and on the bottom surface (which corresponds to the top surface of the conductive structure 120 exposed through the recess 410) of the recess 410. The insulator layer 164 may also be deposited over the top surface of the portion of the dielectric layer 148. In some implementations, a deposition tool is used to conformally deposit the insulator layer 164 using a conformal CVD technique and/or an ALD technique.

The top electrode layer 166 may be deposited on the insulator layer 164. Thus, the top electrode layer 166 is deposited on the sidewalls and on the bottom surface (which corresponds to the top surface of the conductive structure 120 exposed through the recess 410) of the recess 410. The top electrode layer 166 may also be deposited over the top surface of the portion of the dielectric layer 148. In some implementations, a deposition tool is used to conformally deposit the top electrode layer 166 using a conformal CVD technique and/or an ALD technique.

The dielectric filler 168 may be deposited on the top electrode layer 166 such that the dielectric filler 168 fills the remaining area of the recess 410. In some implementations, a deposition tool is used to deposit the dielectric filler 168 using a PVD technique, a CVD technique, an ALD technique, and/or another suitable deposition technique.

As further shown in FIG. 4G, the capping layers 170 and 172 may be formed above the recess 410. For example, the capping layers 170 and 172 may be formed over the top surface of the dielectric layer 148. A deposition tool may be used to deposit the capping layers 170 and 172 using a PVD technique, an ALD technique, a CVD technique, an oxidation technique, and/or another suitable deposition technique. In some implementations, a planarization tool may be used to perform a planarization operation (e.g., a CMP operation) to planarize the capping layers 170 and/or 172 after the capping layers 170 and/or 172 are deposited.

As shown in FIG. 4H, a patterned masking layer 412 may be formed on a portion of the capping layer 172 above the capacitor structure 160. A deposition tool may be used to form the patterned masking layer 412 using a spin-coating technique and/or another suitable deposition technique. An exposure tool may be used to expose the patterned masking layer 412 to a radiation source to pattern the patterned masking layer 412. A developer tool may be used to develop and remove portions of the patterned masking layer 412 to expose the pattern.

As shown in FIG. 4I, the patterned masking layer 412 may be used to etch and define the capping layers 170 and 172, top electrode layer 166, and/or the insulator layer 164 of the capacitor structure 160. An etch tool may be used to etch the capping layers 170 and 172, top electrode layer 166, and/or the insulator layer 164 based on the patterned masking layer 412. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the patterned masking layer 412 (e.g., using a chemical stripper, plasma ashing, and/or another technique).

As shown in FIG. 4J, the sidewall spacers 174 and 176 are formed on the ends of the insulator layer 164, on the ends of the top electrode layer 166, on the ends of the capping layer 170, and/or on the ends of the capping layer 172. A deposition tool may be used to deposit the sidewall spacers 174 and 176 using a PVD technique, an ALD technique, a CVD technique, an oxidation technique, and/or another suitable deposition technique. The sidewall spacers 174 and 176 may be deposited in one or more deposition operations.

As shown in FIG. 4K, another etch operation may be performed to trim the portions of the bottom electrode layer 162 above the top surface of the portion of the dielectric layer 148 to define the bottom electrode layer 162 of the capacitor structure. The capping layer 172 and the sidewall spacers 174 and 176 may be used as a self-aligned mask to etch the bottom electrode layer 162. In some implementations, the etch operation includes a dry etch operation (e.g., a plasma-based etch operation, a gas-based etch operation), a wet chemical etch operation, and/or another type of etch operation.

As shown in FIG. 4L, an additional portion of the dielectric layer 148 may be formed over the top of the capacitor structure 160 and over the first portion of the dielectric layer 148.

The top of the capacitor structure 160 may be encapsulated in the dielectric layer 148. The ESL 150 of the bonding layer 108 may be formed on the dielectric layer 148, the dielectric layer 152 of the bonding layer 108 may be formed on the ESL 150, and the bonding dielectric layer 158 of the bonding layer 108 may be formed on the dielectric layer 152. A deposition tool may be used to deposit the additional portion of the dielectric layer 148, the ESL 150, the dielectric layer 152, and/or the bonding dielectric layer 158 using a PVD technique, an ALD technique, a CVD technique, an oxidation technique, and/or another suitable deposition technique. The additional portion of the dielectric layer 148, the ESL 150, the dielectric layer 152, and/or the bonding dielectric layer 158 may be deposited in one or more deposition operations. In some implementations, a planarization tool may be used to perform a planarization operation (e.g., a CMP operation) to planarize the dielectric layer 148, the ESL 150, the dielectric layer 152, and/or the bonding dielectric layer 158.

As shown in FIG. 4M, a via portion of a recess 414 may be formed above the capacitor structure 160. The via portion of the recess 414 may be formed such that the via portion of the recess 414 extends through the bonding dielectric layer 158, through the dielectric layer 152, through the ESL 150, through a portion of the dielectric layer 148, through the capping layers 170 and 172 of the capacitor structure 160 and to the top electrode layer 166 of the capacitor structure 160. In some implementations, the via portion of the recess 414 is formed into a portion of the top electrode layer 166 such that the bottom of the via portion of the recess 414 is recessed in the top electrode layer 166. Similarly, via portions of recesses 416 may be formed through the bonding dielectric layer 158, through the dielectric layer 152, through the ESL 150, through the dielectric layer 148, through the ESL 146 and to the top metal layers 144 in the interconnect layer 106.

In some implementations, a pattern in a photoresist layer is used to form the via portion of the recess 414 and the via portions of the recesses 416. In these implementations, a deposition tool may be used to form the photoresist layer on the bonding dielectric layer 158 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the bonding dielectric layer 158, through the dielectric layer 152, through the ESL 150, through the dielectric layer 148, through the ESL 146 based on the pattern to form the via portion of the recess 414 and/or the via portions of the recesses 416. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the via portion of the recess 414 and/or the via portion of the recess 416 based on a pattern.

As shown in FIG. 4N, plugs 418 may be formed in bottom portions of the recesses 414 and 416. The plugs 418 may be formed by forming a photoresist layer or another suitable plug material layer (e.g., a dielectric layer) in the via portions of the recesses 414 and 416, and trimming the photoresist layer (e.g., by photolithography) such that remaining portions of the photoresist layer remain in the bottom portions of the recesses 414 and 416.

As shown in FIG. 4O, a trench portion of the recess 414 and trench portions of the recesses 416 are formed through the bonding dielectric layer 158, through the dielectric layer 152, and/or through the ESL 150. Thus, the recesses 414 and 416 may be dual damascene recesses. While FIGS. 4M-4O illustrate a via-first dual damascene process, the recesses 414 and 416 may be formed by a trench-first dual damascene process. The plugs 418 in the bottom portions (e.g., the via portions) of the recesses 414 and 416 protect the bottom portions of the recesses 414 and 416 from further etching (and thus, from further critical dimension widening) during etching of the trench portions of the recesses 414 and 416.

As shown in FIG. 4P, the bonding vias 154 are formed in the via portions of the recesses 414 and 416, and the bonding pads 156 are formed on the bonding vias 154 in the trench portions of the recesses 414 and 416. The bonding via 154 formed in the via portion of the recess 414 lands on the top electrode layer 166 of the capacitor structure 160. As indicated above, the via portion of the recess 414 may extend into a portion of the top electrode layer 166. Accordingly, the bonding via 154 formed in the via portion of the recess 414 may be recessed in a portion of the top electrode layer 166. In other words, the bottom surface of the bonding via 154 formed in the via portion of the recess 414 may be located below the top surface of the top electrode layer 166. The bonding vias 154 formed in the via portions of the recess 416 land on the tops of the top metal layers 144 exposed through the recesses 416.

A deposition tool may be used to deposit the bonding vias 154 and bonding pads 156 using a CVD technique, a PVD technique, an ALD technique, an electroplating technique, and/or another suitable deposition technique. The bonding vias 154 and bonding pads 156 may be deposited in one or more deposition operations. In some implementations, a seed layer is first deposited in the recesses 414 and 416, and the bonding vias 154 and bonding pads 156 are deposited on the seed layer. In some implementations, a liner layer (e.g., an adhesion liner, a barrier liner) is first deposited in the recesses 414 and 416, and the bonding vias 154 and bonding pads 156 are deposited on the liner layer. The liner layer may include a suitable liner material such as a tantalum nitride (TaN) and/or titanium nitride (TiN), among other examples. In some implementations, a planarization tool is used to perform a planarization operation (e.g., a CMP operation) to planarize the bonding pads 156 after the bonding vias 154 and bonding pads 156 are deposited.

As indicated above, FIGS. 4A-4P are provided as an example. Other examples may differ from what is described with regard to FIGS. 4A-4P.

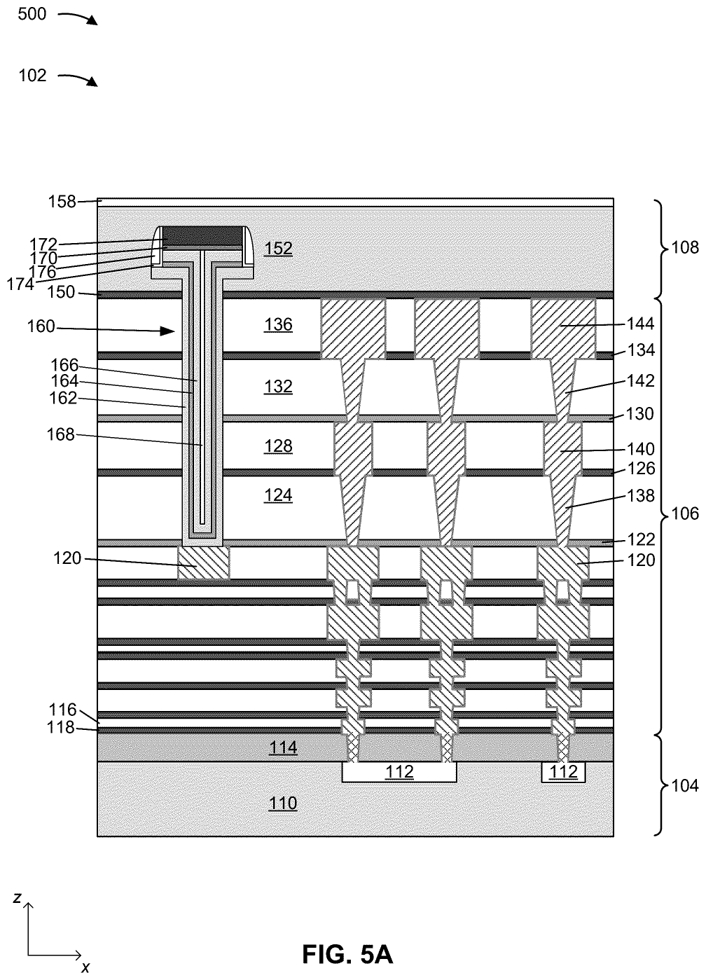

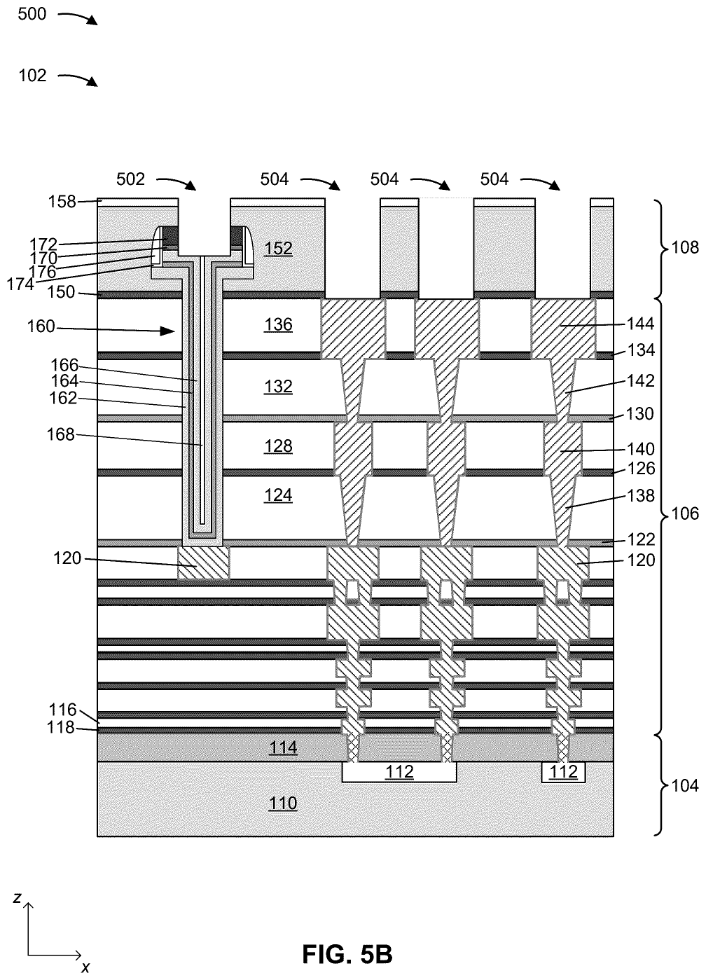

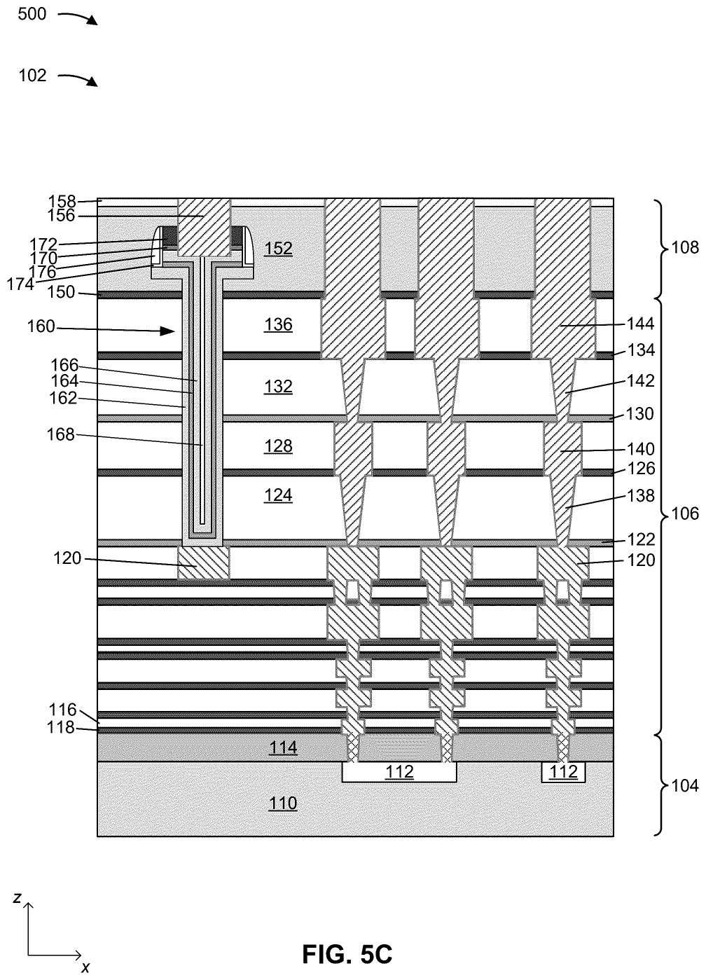

FIGS. 5A-5C are diagrams of an example implementation 500 of forming a semiconductor device 102 described herein. In particular, the example implementation 500 includes an example of forming the example implementation 200 of the semiconductor device 102 illustrated in FIG. 2. However, one or more of the semiconductor processing operations described in connection with FIGS. 5A-5C may be performed to form another example implementation of a semiconductor device 102 described herein. In some implementations, one or more of the semiconductor processing operations described in connection with FIGS. 5A-5C may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 5A, one or more of the semiconductor processing operations described in connection with FIGS. 4A-4K may be performed to form the device layer 104, the interconnect layer 106, and the capacitor structure 160. However, in the example implementation 500, formation of the ESL 146 and formation of the dielectric layer 148 are omitted. Instead, the ESL 150 is formed on the ILD layer 136, the dielectric layer 152 is formed on the ESL 150, and the bonding dielectric layer 158 is formed on the dielectric layer 152. The recess 410 for the capacitor structure 160 may be formed through a portion of the dielectric layer 152 and through the ESL 150 instead of through a portion of the dielectric layer 148 and instead of through the ESL 146.

As shown in FIG. 5B, a recess 502 may be formed above the capacitor structure 160.

The recess 502 may be formed such that the recess 502 extends through the bonding dielectric layer 158, through a portion of the dielectric layer 152, through the capping layers 170 and 172 of the capacitor structure 160, and to the top electrode layer 166 of the capacitor structure 160.

In some implementations, the recess 502 is formed into a portion of the top electrode layer 166 such that the bottom of the recess 502 is recessed in the top electrode layer 166.

As further shown in FIG. 5B, recesses 504 may be formed through the bonding dielectric layer 158, through the dielectric layer 152, and through the ESL 150 to the top metal layers 144. The recess 502 and the recesses 504 may be trench-shaped, pad-shaped, and/or another shape having substantially vertical sidewalls.

As shown in FIG. 5C, a bonding pad 156 is formed in the recess 502 such that the bonding pad 156 lands on the top electrode layer 166 of the capacitor structure 160. As indicated above, the recess 502 may extend into a portion of the top electrode layer 166. Accordingly, the bonding pad 156 may be recessed in a portion of the top electrode layer 166. In other words, the bottom surface of the bonding pad 156 may be located below the top surface of the top electrode layer 166. Bonding pads 156 may also be formed in the recesses 504 such that the bonding pads 156 land on the top metal layers 144. In some implementations, a planarization tool may be used to planarize the bonding pads 156 after the bonding pads 156 are formed in the recesses 502 and 504.

As indicated above, FIGS. 5A-5C are provided as an example. Other examples may differ from what is described with regard to FIGS. 5A-5C.

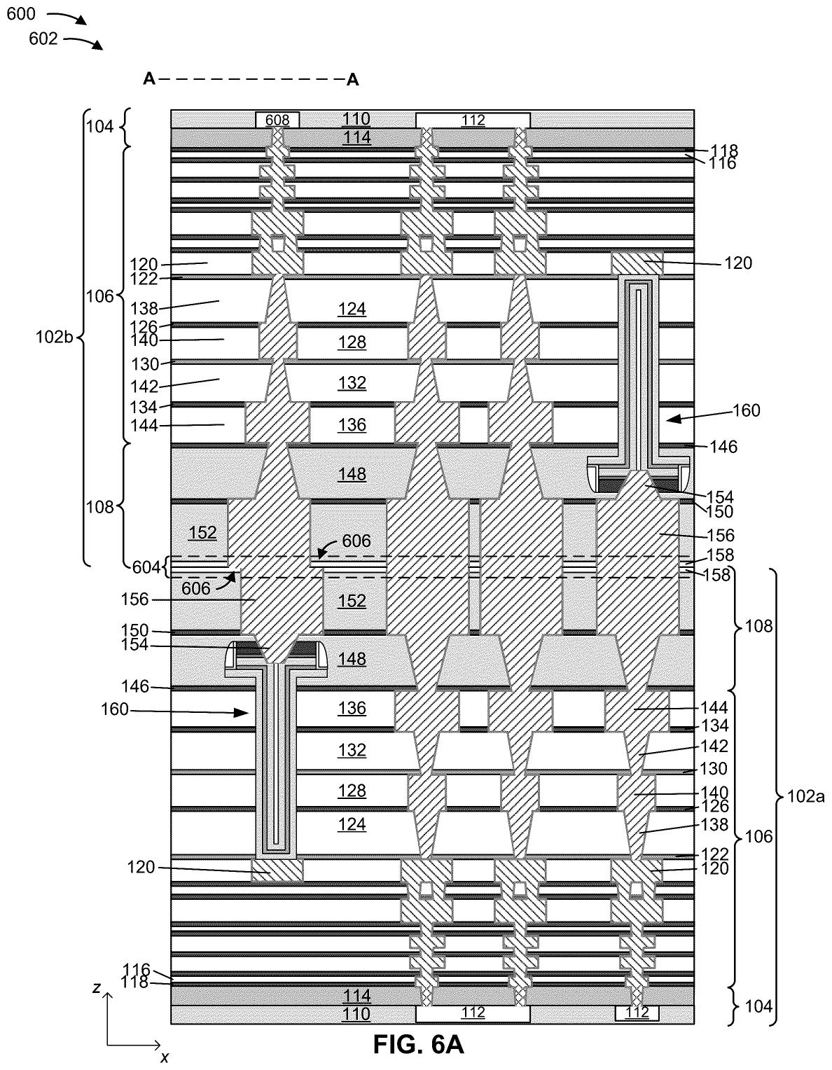

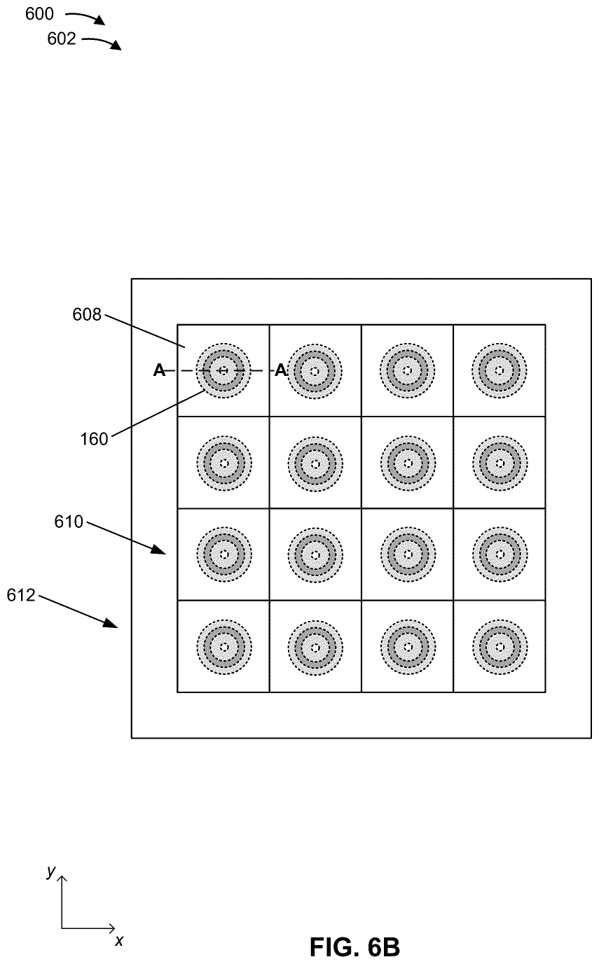

FIGS. 6A and 6B are diagrams of an example implementation 600 of a semiconductor package 602 described herein. As shown in a cross-section view of the semiconductor package 602 in FIG. 6A, the semiconductor package 602 is a 3D structure that includes a semiconductor die 102a and a semiconductor die 102b that are directly bonded together at a bonding interface 604 such that the semiconductor die 102a and the semiconductor die 102b are stacked and vertically arranged in the semiconductor package 602. The semiconductor die 102a and a semiconductor die 102b may each include a similar combination and arrangement of layers and/or structures as the example implementation 100 of the semiconductor device 102 illustrated in FIG. 1, and may be formed by similar semiconductor processing operations and/or techniques as described in connection with FIGS. 4A-4P.

At the bonding interface 604, the semiconductor die 102a and the semiconductor die 102b may be bonded together with a combination of metal-to-metal bonds and dielectric-to-dielectric bonds. For example, the bonding pads 156 of the semiconductor die 102a may be bonded to the bonding pads 156 of the semiconductor die 120b in metal-to-metal bonds at the bonding interface 604. As another example, the bonding dielectric layer 158 of the semiconductor die 102a may be bonded to the bonding dielectric layer 158 of the semiconductor die 102b in a dielectric-to-dielectric bond at the bonding interface 604.

In some implementations, a misalignment may occur at the bonding interface 604 between a bonding pad 156 of the semiconductor die 102a and a bonding pad 156 of the semiconductor die 102b. Thus, misalignment regions 606 may occur on one or more sides of the bond between the bonding pads 156 of the semiconductor dies 102a and 102b. A misalignment region 606 may include a portion of the bonding surface of the bonding pad 156 of the semiconductor die 102a that is in contact with the bonding dielectric layer 158 of the semiconductor die 102b. Another misalignment region 606 may include a portion of the bonding surface of the bonding pad 156 of the semiconductor die 102b that is in contact with the bonding dielectric layer 158 of the semiconductor die 102a. In other words, the bonding pads 156 are laterally offset such that the edges of the bonding pads 156 of the semiconductor dies 102a and 102b that are bonded together may be misaligned.

In some implementations, the semiconductor package 602 is an image sensor device (e.g., a 3D CIS device). Thus, the semiconductor die 102a may include an ASIC die of the image sensor device, and the semiconductor die 102b may include an image sensor die of the image sensor device. Thus, the semiconductor die 102b may include a plurality of pixel sensors 608 in the substrate layer 110 of the semiconductor die 102b. The pixel sensors 608 may be configured to absorb photons of incident light and to convert the photons to a photocurrent for generation of images and/or video. The semiconductor die 102a and/or the semiconductor die 102b may include one or more capacitor structures 160 that are configured to store charge for the pixel sensors 608 to increase the FWC of the pixel sensors 608 and/or to enable global shutter functionality in the semiconductor die 102b.

For example, the semiconductor die 102a may include a capacitor structure 160 that is directly connected to a bonding via 154 in the bonding layer 108 of the semiconductor die 102a. The capacitor structure 160 may be electrically connected to a bonding pad 156 of the semiconductor die 102b through the bonding via 154 and through a bonding pad 156 of the semiconductor die 102a that is physically connected with the bonding via 154 and the bonding pad 156 of the semiconductor die 102b. This enables the capacitor structure 160 included in the semiconductor die 102a to be electrically connected to a pixel sensor 608 included in the semiconductor die 102b.

Additionally and/or alternatively, the semiconductor die 102b may include a capacitor structure 160 that is directly connected to a bonding via 154 in the bonding layer 108 of the semiconductor die 102b. The capacitor structure 160 may be electrically connected to a bonding pad 156 of the semiconductor die 102a through the bonding via 154 and through a bonding pad 156 of the semiconductor die 102b that is physically connected with the bonding via 154 and the bonding pad 156 of the semiconductor die 102a.

FIG. 6B illustrates a top view of the semiconductor package 602, and illustrates an example of a pixel sensor array 610 that includes a plurality of the pixel sensors 608. As shown in FIG. 6B, the pixel sensors 608 may be arranged in a grid in the pixel sensor array 610. As further shown in FIG. 6B, a periphery region 612 may laterally surround the pixel sensor array 610. The periphery region 612 may include other functional structures of the semiconductor package 602, such as black level correction (BLC) structures and/or other pixel circuit components (e.g., source-follower transistors, row-select transistors).

As further shown in FIG. 6B, capacitor structures 160 included in the semiconductor die 102a and/or in the semiconductor die 102b may be located under the pixel sensors 608 of the pixel sensor array 610. The location of a portion of the cross-section shown in FIG. 6A is indicated by the line A-A in FIG. 6B. The bonding pads 156 and the bonding vias 154 of the semiconductor dies 102a and 102b provide “in-pixel” connections between the pixel sensors 608 of the pixel sensor array 610 in that the capacitor structures 160 on the semiconductor die 102a may be positioned under, and electrically connected to, a pixel sensor 608 through bonding vias 154 and bonding pads 156 of the semiconductor dies 102a and 102b under the pixel sensor 608.

As indicated above, FIGS. 6A and 6B are provided as an example. Other examples may differ from what is described with regard to FIGS. 6A and 6B.

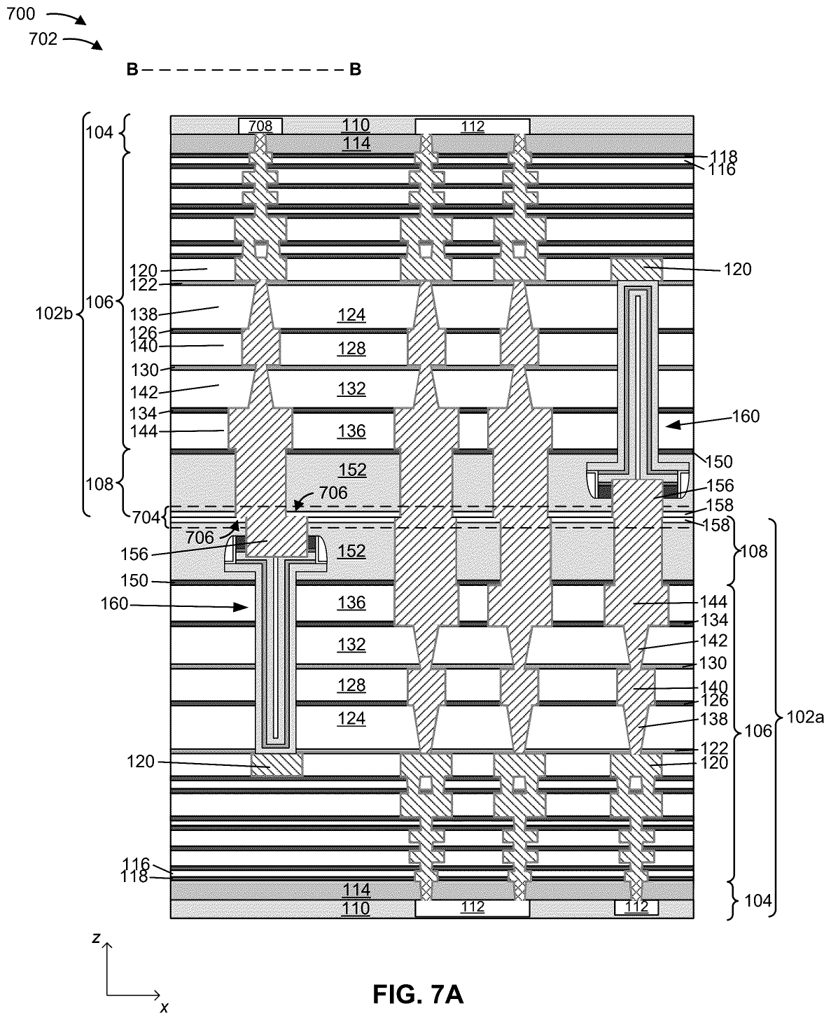

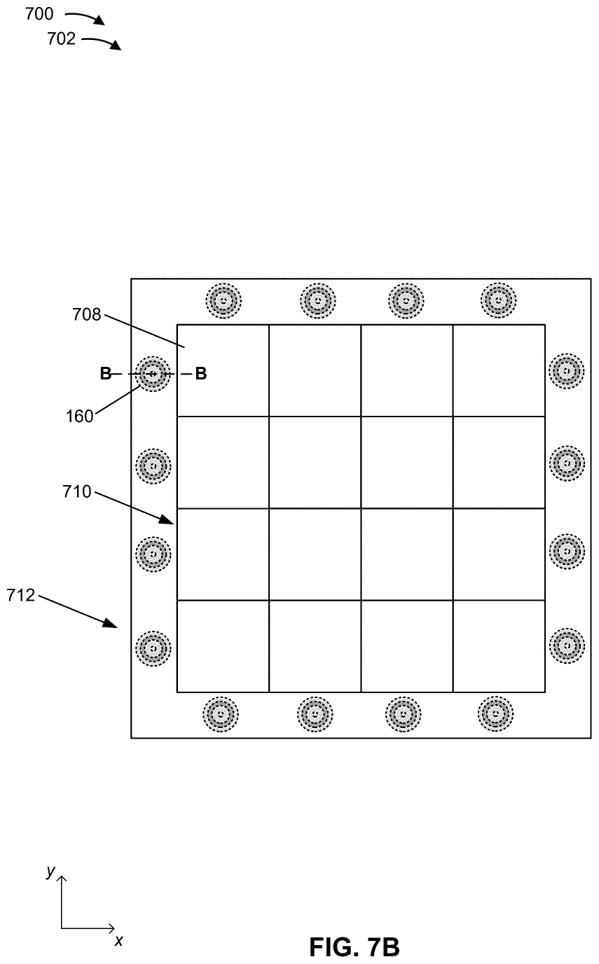

FIGS. 7A and 7B are diagrams of an example implementation 700 of a semiconductor package 702 described herein. As shown in a cross-section view of the semiconductor package 702 in FIG. 7A, the semiconductor package 702 is a 3D structure that includes a semiconductor die 102a and a semiconductor die 102b that are directly bonded together at a bonding interface 704 such that the semiconductor die 102a and the semiconductor die 102b are stacked and vertically arranged in the semiconductor package 702. The semiconductor die 102a and a semiconductor die 102b may each include a similar combination and arrangement of layers and/or structures as the example implementation 200 of the semiconductor device 102 illustrated in FIG. 2, and may be formed by similar semiconductor processing operations and/or techniques as described in connection with FIGS. 4A-4P and/or 5A-5C.

At the bonding interface 704, the semiconductor die 102a and the semiconductor die 102b may be bonded together with a combination of metal-to-metal bonds and dielectric-to-dielectric bonds. For example, the bonding pads 156 of the semiconductor die 102a may be bonded to the bonding pads 156 of the semiconductor die 120b in metal-to-metal bonds at the bonding interface 704. As another example, the bonding dielectric layer 158 of the semiconductor die 102a may be bonded to the bonding dielectric layer 158 of the semiconductor die 102b in a dielectric-to-dielectric bond at the bonding interface 704.

In some implementations, a misalignment may occur at the bonding interface 704 between a bonding pad 156 of the semiconductor die 102a and a bonding pad 156 of the semiconductor die 102b. Thus, misalignment regions 706 may occur on one or more sides of the bond between the bonding pads 156 of the semiconductor dies 102a and 102b. A misalignment region 706 may include a portion of the bonding surface of the bonding pad 156 of the semiconductor die 102a that is in contact with the bonding dielectric layer 158 of the semiconductor die 102b. Another misalignment region 706 may include a portion of the bonding surface of the bonding pad 156 of the semiconductor die 102b that is in contact with the bonding dielectric layer 158 of the semiconductor die 102a. In other words, the bonding pads 156 are laterally offset such that the edges of the bonding pads 156 of the semiconductor dies 102a and 102b that are bonded together may be misaligned.

In some implementations, the semiconductor package 702 is an image sensor device (e.g., a 3D CIS device). Thus, the semiconductor die 102a may include an ASIC die of the image sensor device, and the semiconductor die 102b may include an image sensor die of the image sensor device. Thus, the semiconductor die 102b may include a plurality of pixel sensors 708 in the substrate layer 110 of the semiconductor die 102b. The pixel sensors 708 may be configured to absorb photons of incident light and to convert the photons to a photocurrent for generation of images and/or video. The semiconductor die 102a and/or the semiconductor die 102b may include one or more capacitor structures 160 that are configured to store charge for the pixel sensors 708 to increase the FWC of the pixel sensors 708 and/or to enable global shutter functionality in the semiconductor die 102b.

For example, the semiconductor die 102a may include a capacitor structure 160 that is directly connected to a bonding pad 156 in the bonding layer 108 of the semiconductor die 102a. The capacitor structure 160 may be electrically connected to a bonding pad 156 of the semiconductor die 102b through the bonding pad 156 of the semiconductor die 102a (which is bonded to the bonding pad 156 on the semiconductor die 102b). This enables the capacitor structure 160 included in the semiconductor die 102a to be electrically connected to a pixel sensor 708 included in the semiconductor die 102b.

Additionally and/or alternatively, the semiconductor die 102b may include a capacitor structure 160 that is directly connected to a bonding pad 156 in the bonding layer 108 of the semiconductor die 102b. The capacitor structure 160 may be electrically connected to a bonding pad 156 of the semiconductor die 102a through the bonding pad 156 of the semiconductor die 102b (which is bonded to the bonding pad 156 on the semiconductor die 102a).

FIG. 7B illustrates a top view of the semiconductor package 702, and illustrates an example of a pixel sensor array 710 that includes a plurality of the pixel sensors 708. As shown in FIG. 7B, the pixel sensors 708 may be arranged in a grid in the pixel sensor array 710. As further shown in FIG. 7B, a periphery region 712 may laterally surround the pixel sensor array 710. The periphery region 712 may include other functional structures of the semiconductor package 702, such as BLC structures and/or other pixel circuit components (e.g., source-follower transistors, row-select transistors).

As further shown in FIG. 7B, capacitor structures 160 included in the semiconductor die 102a and/or in the semiconductor die 102b may be located around the pixel sensor array 710.

For example, capacitor structures 160 may be located in the periphery region 712, which may correspond to a die edge or die perimeter of the semiconductor die 102a and/or of the semiconductor die 102b. The location of a portion of the cross-section shown in FIG. 7A is indicated by the line B-B in FIG. 7B. The bonding pads 156 around the perimeters of the semiconductor dies 102a and 102b provide connections between the pixel sensors 708 of the pixel sensor array 710 and the capacitor structures 160 on the semiconductor die 102a.

As indicated above, FIGS. 7A and 7B are provided as an example. Other examples may differ from what is described with regard to FIGS. 7A and 7B.

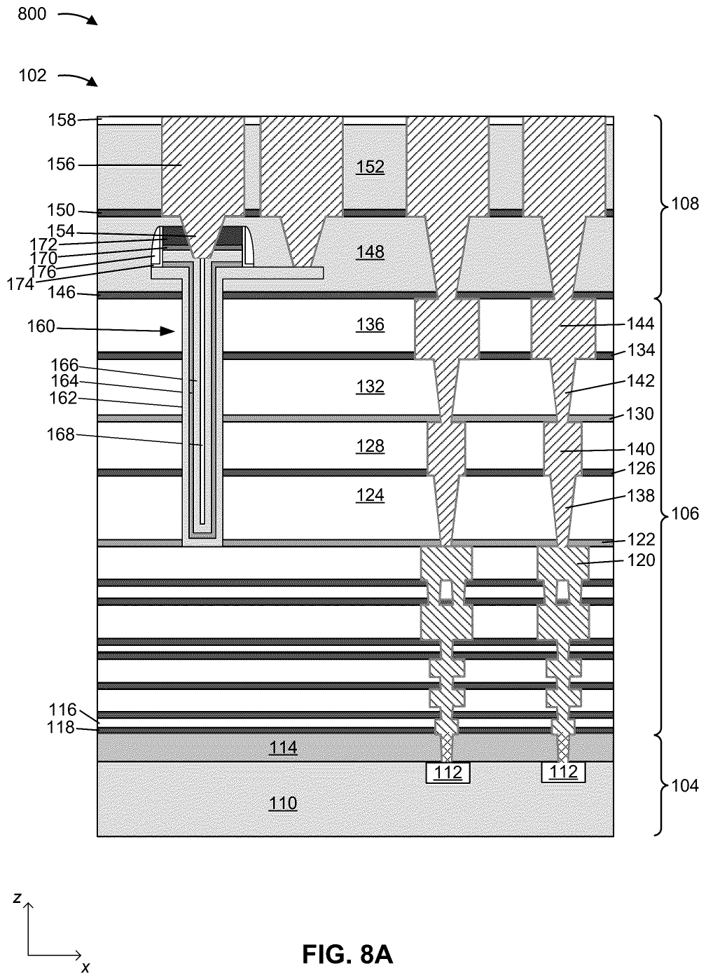

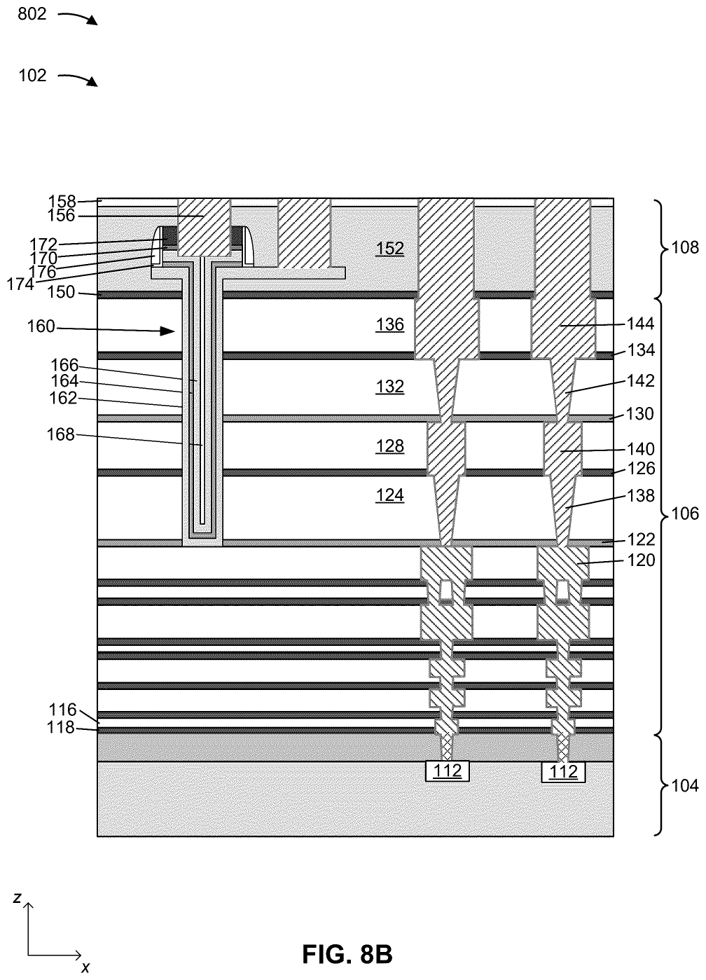

FIGS. 8A and 8B are diagrams of example implementations of the semiconductor device 102 described herein. As shown in FIG. 8A, an example implementation 800 of the semiconductor device 102 may include a similar combination and arrangement of layers and/or structures as the example implementation 100 of the semiconductor device 102 illustrated in FIG. 1. However, in the example implementation 800 in FIG. 8A, the bottom electrode layer 162 of the capacitor structure 160 is directly connected (e.g., physically and/or electrically) to another bonding via 154 in the bonding layer 108, in addition to the top electrode layer 166 of the capacitor structure 160 being directly connected (e.g., physically and/or electrically) to a bonding via 154. Thus, the bottom electrode layer 162 and the top electrode layer 166 of the capacitor structure 160 each have top connections at the top of the capacitor structure 160 in the example implementation 800 in FIG. 8A, as opposed to the bottom electrode layer 162 of the capacitor structure 160 having a bottom connection in the interconnect layer 106 at the bottom of the capacitor structure 160 in the example implementation 100 in FIG. 1.

As shown in FIG. 8B, an example implementation 802 of the semiconductor device 102 may include a similar combination and arrangement of layers and/or structures as the example implementation 200 of the semiconductor device 102 illustrated in FIG. 2. However, in the example implementation 802 in FIG. 8B, the bottom electrode layer 162 of the capacitor structure 160 is directly connected (e.g., physically and/or electrically) to another bonding pad 156 in the bonding layer 108, in addition to the top electrode layer 166 of the capacitor structure 160 being directly connected (e.g., physically and/or electrically) to a bonding pad 156. Thus, the bottom electrode layer 162 and the top electrode layer 166 of the capacitor structure 160 each have top connections at the top of the capacitor structure 160 in the example implementation 802 in FIG. 8B, as opposed to the bottom electrode layer 162 of the capacitor structure 160 having a bottom connection in the interconnect layer 106 at the bottom of the capacitor structure 160 in the example implementation 200 in FIG. 2.

As indicated above, FIGS. 8A and 8B are provided as examples. Other examples may differ from what is described with regard to FIGS. 8A and 8B.

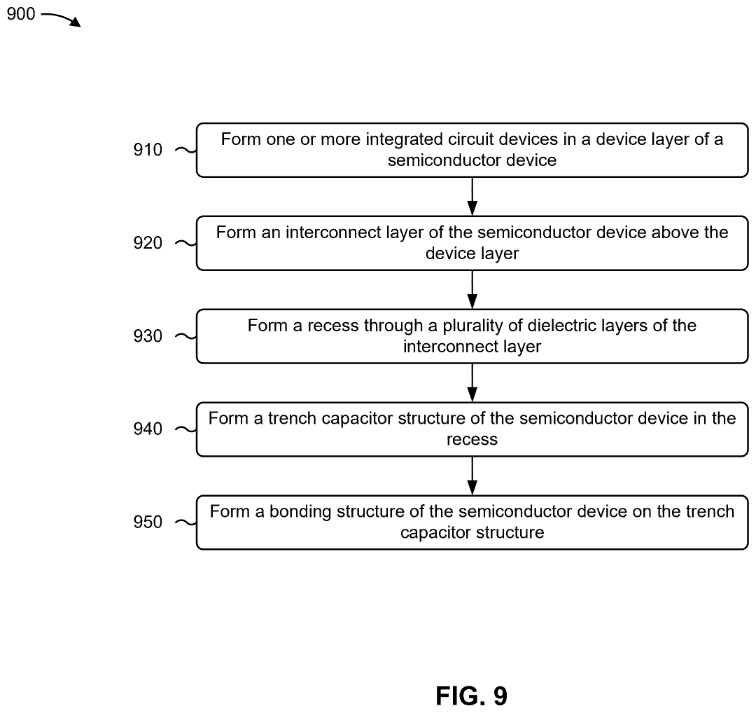

FIG. 9 is a flowchart of an example process 900 associated with forming a semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming one or more integrated circuit devices in a device layer of a semiconductor device (block 910). For example, one or more semiconductor processing tools may be used to form one or more integrated circuit devices (e.g., one or more integrated circuit devices 112) in a device layer (e.g., a device layer 104) of a semiconductor device (e.g., a semiconductor device 102, a semiconductor die 102a, a semiconductor die 102b), as described herein.

As further shown in FIG. 9, process 900 may include forming an interconnect layer of the semiconductor device above the device layer (block 920). For example, one or more semiconductor processing tools may be used to form an interconnect layer (e.g., an interconnect layer 106) of the semiconductor device above the device layer, as described herein.

As further shown in FIG. 9, process 900 may include forming a recess through a plurality of dielectric layers of the interconnect layer (block 930). For example, one or more semiconductor processing tools may be used to form a recess (e.g., a recess 410) through a plurality of dielectric layers (e.g., ESLs 122, 126, 130, 134, and/or 146, ILD layers 124, 128, 132, and/or 126) of the interconnect layer, as described herein.

As further shown in FIG. 9, process 900 may include forming a trench capacitor structure of the semiconductor device in the recess (block 940). For example, one or more semiconductor processing tools may be used to form a trench capacitor structure (e.g., a capacitor structure 160) of the semiconductor device in the recess, as described herein.

As further shown in FIG. 9, process 900 may include forming a bonding structure of the semiconductor device on the trench capacitor structure (block 950). For example, one or more semiconductor processing tools may be used to form a bonding structure (e.g., a bonding via 154, a bonding pad 156) of the semiconductor device on the trench capacitor structure, as described herein.

Process 900 may include additional implementations, such as any single implementation or any combination of implementations described below and/or in connection with one or more other processes described elsewhere herein.

In a first implementation, process 900 includes bonding the semiconductor device to another semiconductor device (e.g., a semiconductor device 102, a semiconductor die 102a, a semiconductor die 102b) such that the bonding structure is directly bonded to another bonding structure (e.g., a bonding pad 156) of the other semiconductor device.

In a second implementation, alone or in combination with the first implementation, process 900 includes forming a bonding dielectric layer (e.g., a bonding dielectric layer 158), forming the bonding structure through the bonding dielectric layer, and bonding the semiconductor device to the other semiconductor device such that the bonding dielectric layer is directly bonded to another bonding dielectric layer (e.g., another bonding dielectric layer 158) around the other bonding structure of the other semiconductor device.

In a third implementation, alone or in combination with one or more of the first and second implementations, the bonding structure and the other bonding structure are misaligned such that a first portion of a bonding surface of the bonding structure is bonded to the other bonding structure, and such that a second portion (e.g., a misalignment region 706) of the bonding surface is in contact with the other bonding dielectric layer.

In a fourth implementation, alone or in combination with one or more of the first through third implementations, forming the bonding structure includes forming a bonding via (e.g., a bonding via 154) on a top electrode (e.g., a top electrode layer 166) of the trench capacitor structure, and the process 900 includes forming a bonding pad (e.g., a bonding pad 156) on the bonding via.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a capacitor structure is included in an interconnect layer of a semiconductor die that is bonded to another semiconductor die in a vertical stack in a semiconductor die. To enable the vertical length of the capacitor structure to be increased, the top electrode layer of the capacitor structure is directly connected to a bonding structure of the semiconductor die, as opposed to the top electrode layer of the capacitor structure being connected to the bonding structure through one or more intermediate conductive structures in the interconnect layer. This enables the capacitor structure to vertically extend through a greater quantity of layers of the interconnect layer, which increases the length of the top and bottom electrode layers of the capacitor structure, which increases the capacitance of the capacitor structure. The increased capacitance of the capacitor structure may enable increased performance for the semiconductor device to be achieved.

As described in greater detail above, some implementations described herein provide a semiconductor device. The semiconductor device includes a device layer. The semiconductor device includes one or more integrated circuit devices in the device layer. The semiconductor device includes an interconnect layer above the device layer. The semiconductor device includes one or more conductive structures in the interconnect layer. The semiconductor device includes one or more bonding structures above the interconnect layer. The semiconductor device includes a trench capacitor structure directly coupled to a bonding structure of the one or more bonding structures.

As described in greater detail above, some implementations described herein provide a semiconductor package. The semiconductor package includes a first semiconductor die and a second semiconductor die. The first semiconductor die includes a first interconnect layer, one or more first conductive structures in the first interconnect layer, a first plurality of bonding structures above the first interconnect layer, and a trench capacitor structure directly coupled to a first bonding structure of the first plurality of bonding structures. The second semiconductor die is bonded to the first semiconductor die at a bonding interface such that the first semiconductor die and the second semiconductor die are vertically arranged in the semiconductor package. The second semiconductor die includes a second interconnect layer, one or more second conductive structures in the second interconnect layer, and a second plurality of bonding structures below the second interconnect layer. A second bonding structure of the second plurality of bonding structures is electrically coupled to the first bonding structure.

As described in greater detail above, some implementations described herein provide a method. The method includes forming one or more integrated circuit devices in a device layer of a semiconductor device. The method includes forming an interconnect layer of the semiconductor device above the device layer. The method includes forming a recess through a plurality of dielectric layers of the interconnect layer. The method includes forming a trench capacitor structure of the semiconductor device in the recess. The method includes forming a bonding structure of the semiconductor device on the trench capacitor structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer;
one or more integrated circuit devices in the device layer;
an interconnect layer above the device layer;
one or more conductive structures in the interconnect layer;
one or more bonding structures above the interconnect layer; and
a trench capacitor structure directly coupled to a bonding structure of the one or more bonding structures.

2. The semiconductor device of claim 1, wherein the bonding structure comprises a bonding via;
wherein the one or more bonding structures comprises a bonding pad; and
wherein the bonding pad is coupled to the bonding via.

3. The semiconductor device of claim 2, wherein a top electrode layer of the trench capacitor structure is in contact with the bonding via; and
wherein a bottom electrode layer of the trench capacitor structure is in contact with a conductive structure of the one or more conductive structures.

4. The semiconductor device of claim 3, wherein a bottom surface of the bond via is recessed in the top electrode layer.

5. The semiconductor device of claim 1, wherein the bonding structure comprises a bonding pad.

6. The semiconductor device of claim 5, wherein a top electrode layer of the trench capacitor structure is in contact with the bonding pad; and
wherein a bottom electrode layer of the trench capacitor structure is in contact with a conductive structure of the one or more conductive structures.

7. The semiconductor device of claim 6, wherein a bottom surface of the bonding pad is recessed in the top electrode layer.

8. A semiconductor package, comprising:
a first semiconductor die, comprising:
a first interconnect layer;
one or more first conductive structures in the first interconnect layer; and
a first plurality of bonding structures above the first interconnect layer; and
a trench capacitor structure directly coupled to a first bonding structure of the first plurality of bonding structures; and
a second semiconductor die bonded to the first semiconductor die at a bonding interface such that the first semiconductor die and the second semiconductor die are vertically arranged in the semiconductor package,
wherein the second semiconductor die comprises:
a second interconnect layer;
one or more second conductive structures in the second interconnect layer; and
a second plurality of bonding structures below the second interconnect layer,
wherein a second bonding structure of the second plurality of bonding structures is electrically coupled to the first bonding structure.

9. The semiconductor package of claim 8, wherein the first bonding structure comprises a first bonding pad; and
wherein the second bonding structure comprises a second bonding pad.

10. The semiconductor package of claim 9, wherein the first bonding pad is bonded to the second bonding pad; and
wherein the first bonding pad is laterally offset relative to the second bonding pad.

11. The semiconductor package of claim 9, wherein the second semiconductor die further comprises:
a pixel sensor array that includes a plurality of pixel sensors,
wherein the trench capacitor structure is located under the pixel sensor array.

12. The semiconductor package of claim 8, wherein the first bonding structure comprises a bonding via; and
wherein the second bonding structure comprises a bonding pad.

13. The semiconductor package of claim 12, wherein the bonding via is coupled to another bonding pad in the second semiconductor die; and
wherein the bonding pad in the second semiconductor die is bonded to the other bonding pad in the first semiconductor die.

14. The semiconductor package of claim 12, wherein the second semiconductor die further comprises:
a pixel sensor array that includes a plurality of pixel sensors,
wherein the trench capacitor structure is located under a periphery region that laterally surrounds the pixel sensor array.

15. The semiconductor package of claim 8, wherein the second semiconductor die further comprises:
another trench capacitor structure directly coupled to a third bonding structure of the second plurality of bonding structures of the second semiconductor die,
wherein a fourth bonding structure of the first plurality of bonding structures of the first semiconductor die is electrically coupled to the third bonding structure of the second semiconductor die.

16. A method, comprising:
forming one or more integrated circuit devices in a device layer of a semiconductor device;
forming an interconnect layer of the semiconductor device above the device layer;
forming a recess through a plurality of dielectric layers of the interconnect layer;
forming a trench capacitor structure of the semiconductor device in the recess; and
forming a bonding structure of the semiconductor device on the trench capacitor structure.

17. The method of claim 16, further comprising:
bonding the semiconductor device to another semiconductor device such that the bonding structure is directly bonded to another bonding structure of the other semiconductor device.

18. The method of claim 17, further comprising:
forming a bonding dielectric layer; and
forming the bonding structure through the bonding dielectric layer; and
bonding the semiconductor device to the other semiconductor device such that the bonding dielectric layer is directly bonded to another bonding dielectric layer around the other bonding structure of the other semiconductor device.

19. The method of claim 18, wherein the bonding structure and the other bonding structure are misaligned such that a first portion of a bonding surface of the bonding structure is bonded to the other bonding structure, and such that a second portion of the bonding surface is in contact with the other bonding dielectric layer.

20. The method of claim 16, wherein forming the bonding structure comprises:
forming a bonding via on a top electrode layer of the trench capacitor structure,
wherein the method further comprises:
forming a bonding pad on the bonding via.
